(19) United States
(12) Patent Application Publication
(10) Pub. No.: US 2026/0354098 A1
(43) Pub. Date: Nov. 5, 2026

(54) VERIFICATION PROCESSES FOR AN INTEGRATED SUBSTRATE MEASUREMENT SYSTEM

(71) Applicant: Applied Materials, Inc., Santa Clara, CA (US)

(72) Inventors: Ozkan Celik, Cedar Park, TX (US); Natalia Hermanovna Kroupnova, Palo Alto, CA (US); Rutwik Padmakar Kulkarni, San Jose, CA (US); Michael Kutney, Santa Cruz, CA (US); Jon Edward Meyer, Fremont, CA (US); Duy Tu Nguyen, San Jose, CA (US); Ami Sade, Sunnyvale, CA (US); Vignesh Kumar Venkateshwar, Santa Clara, CA (US); Zhaozhao Zhu, Milpitas, CA (US)

(21) Appl. No.: 19/195,020

(22) Filed: Apr. 30, 2025

(51) Int. Cl. H10P 72/50; G01B 11/03; G01B 11/06; H10P 72/70

(52) U.S. Cl. CPC H10P 72/53; G01B 11/0625; H10P 72/70; G01B 11/03; G01B 2210/56

(57) ABSTRACT

A device includes a calibration target attached to a chuck. The device also includes a camera fixed in a first position. The device also includes a reflectometer fixed in a second position. The device also includes one or more processing devices. The device also includes memory storing instructions that, when executed by the one or more processing devices, cause the device to move the chuck to a third position, capture an image using the camera, determine, using the image, a first actual position of the calibration target, determine a first offset value corresponding to a difference between a first expected position of the calibration target and the first actual position of the calibration target, and verify a calibration of the reflectometer using one or more of the first expected position of the calibration target or the first actual position of the calibration target.

### TECHNICAL FIELD

Some embodiments of the disclosure relate, in general, to substrate measurement, and more particularly to integrated substrate measurement system.

### BACKGROUND

Substrate manufacturing often involves producing the foundational layers that support microelectronic components, such as semiconductor packages or printed circuit boards (PCBs). This processing typically operates on tight dimensional and material tolerances to ensure signal integrity, mechanical reliability, and alignment with downstream assembly processes. Processes and techniques are developed to maintain such precision of tools and alignment systems.

### SUMMARY

In a first example embodiment of a first aspect, a device includes a calibration target attached to a chuck. The device also includes a camera fixed in a first position. The device also includes a reflectometer fixed in a second position. The device also includes one or more processing devices. The device also includes memory storing instructions that, when executed by one or more processing devices, causes the device to move the chuck to a third position, capture an image using the camera, determine, using the image, a first actual position of the calibration target, determine a first offset value corresponding to a difference between a first expected position of the calibration target and the first actual position of the calibration target, and verify a calibration of the reflectometer using one or more of the first expected position of the calibration target or the first actual position of the calibration target.

In a second example embodiment of the first aspect, a method of determining drift characteristics of a substrate processing device includes a fixed camera in a first position and a fixed reflectometer in a second position, the method includes after moving a chuck to a third position, capturing an image using the camera, determining, using the image, a first actual position of a calibration target attached to the chuck, determining a first offset value corresponding to a difference between a first expected position of the calibration target and the first actual position of the calibration target, and verifying calibration of the reflectometer using one or more of the first expected position of the calibration target or the first actual position of the calibration target.

In a third example embodiment of the first aspect, a device includes a calibration target attached to a chuck. The device also includes a camera fixed in a first position. The device also includes a reflectometer fixed in a second position. The device also includes one or more processing devices. The device also includes memory storing instructions that, when executed by the one or more processing devices, cause the device to determine, using the camera, a first actual position of the calibration target, after moving the chuck to a third position based on the first actual position of the calibration target, perform a scan using the reflectometer to determine a second actual position of the calibration target, and calculate an offset value corresponding to a difference between an expected position of the calibration target and the second actual position of the calibration target. The device also includes, based on the second offset value exceeding a threshold, performing one or more corrective actions.

In a first example embodiment of a second aspect, a method includes receiving first spectrograph data corresponding to a first material type, receiving second spectrograph data correspond to a second material type different than the first material type, generating first ratio data by comparing respective values of the first and second spectrograph data, generating a first drift value using the first ratio data, and performing one or more corrective actions based on a determination that the first drift value exceeds a first threshold.

In a second example embodiment of the second aspect, a device includes a reflectometer. The device also includes one or more processing devices. The device also includes memory storing instructions that, when executed by the one or more processing devices, cause the device to generate, using the reflectometer, first spectrograph data corresponding to a first material type, generate, using the reflectometer, second spectrograph data corresponding to a second material type different than the first material type, generate first ratio data by comparing respective values of the first and second spectrograph data, generate a first drift value using the first ratio data, and perform one or more corrective actions based on a determination that the first drift value exceeds a first threshold.

In a third example embodiment of the second aspect, a method includes receiving a plurality of sets of spectrograph data includes a first set of spectrograph data, generating an averaged set of spectrograph data by averaging respective values of the plurality of sets of spectrograph data that each correspond to a same wavelength, generating first ratio data by comparing respective values of the spectrograph data and the averaged set of spectrograph data that correspond to a same wavelength, determining that a normalized value calculated using at least a portion of the first ratio data exceeds a first threshold, and performing one or more corrective actions based on the normalized value exceeding the first threshold.

In a first example embodiment of a third aspect, a method includes loading a substrate on a chuck, determining one or more offset values representing an offset between a center of the chuck and a center of the substrate by performing a first alignment verification operation includes capturing first image data corresponding to an edge of the substrate, determining an orientation of a spatial arrangement of pattern features disposed on the substrate by performing, using the one or more offset values, a second alignment verification operation includes capturing second image data corresponding to a first plurality of alignment marks disposed on the substrate, and performing, using the one or more offset values and the orientation of the spatial arrangement of pattern features disposed on the substrate, a reflectometry operation to verify the quality of one or more substrate characteristics.

In a second example embodiment of the third aspect, a device includes one or more processors. The device also includes a memory storing instructions that, when executed by the one or more processors, configure the device to load a substrate on a chuck, determine one or more offset values representing an offset between a center of the chuck and a center of the substrate by performing a first alignment verification operation includes capturing first image data corresponding to an edge of the substrate, determine an orientation of a spatial arrangement of pattern features disposed on the substrate by performing, using the one or more offset values, a second alignment verification operation includes capturing second image data corresponding to a first plurality of alignment marks disposed on the substrate, and perform, using the one or more offset values and the orientation of the spatial arrangement of pattern features disposed on the substrate, a reflectometry operation to verify the quality of one or more substrate characteristics.

In a third example embodiment of the third aspect, a substrate processing system includes a stage includes a chuck, a linear actuator to adjust the chuck along a first axis, and a rotation actuator to rotate the chuck about a second axis. The substrate processing system also includes one or more processors. The substrate processing system also includes a memory storing instructions that, when executed by the one or more processors, configure the device to load a substrate on the chuck, determine one or more offset values representing an offset between a center of the chuck and a center of the substrate by performing a first alignment verification operation includes capturing first image data corresponding to an edge of the substrate, determine an orientation of a spatial arrangement of pattern features disposed on the substrate by performing, using the one or more offset values, a second alignment verification operation includes capturing second image data corresponding to a first plurality of alignment marks disposed on the substrate, and perform, using the one or more offset values and the orientation of the spatial arrangement of pattern features disposed on the substrate, a reflectometry operation to verify the quality of one or more substrate characteristics.

### BRIEF DESCRIPTION OF THE DRAWINGS

The disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 is a top schematic view of an example processing system, according to one embodiment.

FIG. 2A is a cross-sectional schematic diagram of an Integrated Reflectometer (IR) system with a rotational actuator and a linear actuator according to one embodiment.

FIG. 2B is a top-down schematic diagram of a substrate holder of the IR system of FIG. 2A according to one embodiment.

FIG. 3 is a schematic diagram representing rotational and linear coordinates of a substrate holder of an IR system according to one embodiment.

FIG. 4 is a schematic diagram of a substrate placed on a substrate holder according to one embodiment.

FIG. 5A to FIG. 5D are a series of graphs illustrating example transformations for a circular trajectory according to one embodiment.

FIG. 6 is a block diagram of a method of performing coordinate transformations to correct for substrate and substrate holder offset according to one embodiment.

FIG. 7 is a flow chart of a method of performing coordinate transformations to correct for substrate and substrate holder offset according to one embodiment.

FIG. 8 is a top-down schematic diagram representing rotational and/or linear offsets of a processing system including a camera and a reflectometer, according to one embodiment.

FIG. 9 is a flowchart illustrating a method of calibrating and/or validating a position of a camera within a processing system, according to one embodiment.

FIG. 10 is an exemplary image of the pin as described above with respect to FIG. 9, according to one embodiment.

FIG. 11 is a flowchart illustrating a method of calibrating and/or validating a position of a reflectometer or other sensor within a processing system, according to one embodiment.

FIG. 12 is a flowchart illustrating a method of verifying quality of spectrograph data generated using a reflectometer system, according to one embodiment.

FIG. 13 illustrates a model training workflow and a model application workflow for a process drift determination and a film thickness determination according to one embodiment.

FIG. 14 illustrates a substrate pattern on a substrate with a notch, according to one embodiment.

FIG. 15 illustrates an affine transform, which is used to align an observed substrate pattern with an expected substrate pattern, according to one embodiment.

FIG. 16 illustrates a quiver plot, which depicts error vectors for different positions on the substrate, according to one embodiment.

FIG. 17 illustrates a method of verifying an alignment of a substrate placed on a chuck or stage of a substrate processing system, according to one embodiment.

FIG. 18 depicts a block diagram of an example computing device capable of performing reflectometry verification or calibration, camera offset verification or calibration, reflectometry offset verification or calibration, and/or substrate alignment verification or calibration, operating in accordance with one or more aspects of the disclosure.

### DETAILED DESCRIPTION

Embodiments described herein are related to systems and methods for verifying and/or calibrating positional offsets of different components of a substrate processing system. Embodiments described herein are related to systems and methods for verifying quality of spectrograph or image data.

In modular substrate processing systems, calibration of different components, such as sensors and actuators, may be verified. For example, a target pin on a chuck may be positioned underneath a fixed camera to determine an offset between an expected position of the target pin and the actual position of the target pin. However, in many cases, such modular substrate processing systems are limited as to how the chuck may be moved and/or an overall resolution of the offset. Additionally, conventional verification processes typically do not verify a position of a sensor like, for example reflectometer (or other sensor type other than a camera), and instead rely on a pre-determined relationship between the camera and the reflectometer. For example, conventional systems may rely on the relative position between camera and reflectometer, which may only be calibrated during startup activities and not being verified or monitored throughout system lifetime. As a result, an offset between the chuck and reflectometer can occur due to various reasons (hardware wear out, external impact, malfunction, or the like). Here, calibration of relative position between camera and reflectometer could only be performed by re-calibrating the system as a whole, which invalidate the existing calibrated positions and can potentially waste time (e.g., if the existing calibrated positions are still good). This results in a less accurate estimation of an offset between the chuck and the reflectometer.

Additionally, conventional substrate processing systems may verify that a reflectometer (or other spectrographic sensor) is providing accurate spectrograph data by analyzing material with known spectral characteristics as a reference and analyzing properties of the spectrograph data such as signal-to-noise ratio, spectral peak positions, baseline stability, or the like. However, conventional processes to verify that a reflectometer is working correctly may not provide results within a target tolerance level.

Also, substrate placement offset may conventionally be calibrated and/or verified after load-in by imaging and identifying alignment marks on the loaded substrate. However, conventional substrate placement offset verification processes may not calculate adequate directional and/or rotational offset estimates for more advanced substrate processing techniques. Additionally, conventional substrate placement offset verification processes may be time-consuming and may decrease overall substrate production efficiency.

Aspects and embodiments of the present disclosure address the above problems and/or others by providing a substrate processing system that sequentially performs a camera offset verification process and a reflectometry verification process. According to embodiments, a device may include a pin attached to a chuck. The device may also include a camera fixed in a first position and a reflectometer fixed in a second position. The device may also include one or more processing devices and memory storing instructions that, when executed by the one or more processing devices, cause the device to perform an offset verification process. This offset verification process may include capturing an image using the camera after moving the chuck to a third position. Then, using the image, a first actual position of the pin may be determined. Then, a first offset value corresponding to a difference between a first expected position of the pin and the first actual position of the pin may be determined. Then, using the first offset value, a calibration of the reflectometer using one or more of the first expected position of the pin or the first actual position of the pin may be verified.

Aspects and embodiments of the present disclosure address the above problems and/or others by providing a substrate processing system that performs a spectrograph quality verification process. According to embodiments, the spectrograph quality verification process includes receiving first spectrograph data corresponding to a first material type (e.g., silicon), and receiving second spectrograph data correspond to a second material type (e.g., silicon dioxide) different than the first material type. The spectrograph quality verification process may include generating first ratio data by comparing respective values of the first and second spectrograph data, and generating a first drift value using the first ratio data. Then, based on a determination that the first drift value exceeds a first threshold, one or more corrective actions may be performed.

Aspects and embodiments of the present disclosure address the above problems and/or others by providing a substrate processing system that performs an alignment verification process. According to embodiments, the alignment verification process includes loading a substrate on a chuck and determining one or more offset values representing an offset between a center of the chuck and a center of the substrate. These one or more offset values may be determined by performing a first alignment verification operation that includes capturing first image data corresponding to an edge of the substrate. Then, the alignment verification process may include determining an orientation of a spatial arrangement of pattern features disposed on the substrate. This orientation may be determined by performing, using one or more offset values, a second alignment verification operation that includes capturing second image data corresponding to a first plurality of alignment marks disposed on the substrate. Then, using the one or more offset values and the orientation of the spatial arrangement of pattern features disposed on the substrate, a reflectometry operation to verify signal quality from one or more of the substrates may be performed.

Aspects and embodiments of the present disclosure may provide one or more advantages over conventional substrate processing systems, such as, for example, providing verification processes (resulting in higher substrate processing throughput), achieving tighter verification tolerance thresholds, or the like. Aspects and embodiments of the present disclosure can verify before-calibrated positions of components (e.g., camera, reflectometer) without triggering re-calibration. Aspects and embodiments of the present disclosure can provide verification services automatically without user intervention. Aspects and embodiments of the present disclosure can provide warnings to users if tolerances of calibrated positions of components are exceeded.

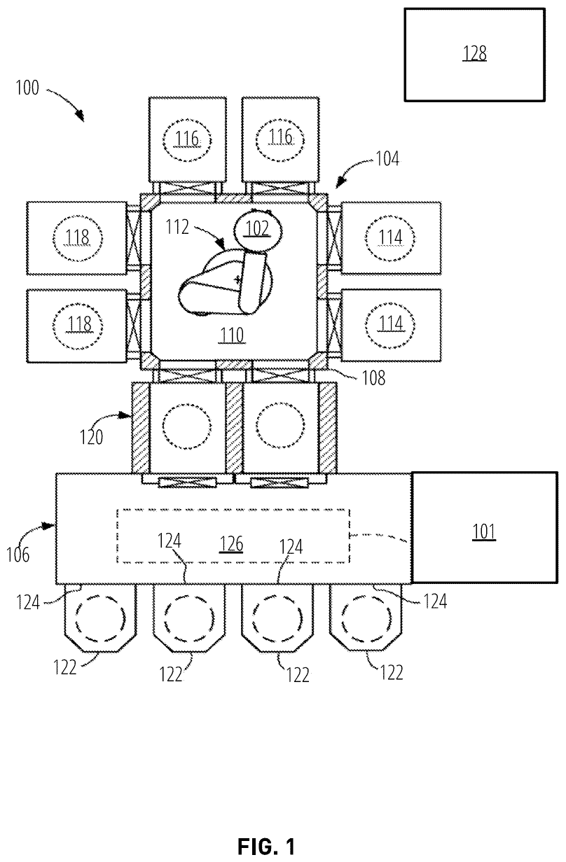

FIG. 1 is a top schematic view of an example processing system 100, according to one embodiment. In some embodiments, processing system 100 may be an electronics processing system configured to perform one or more processes on a substrate 102. In some embodiments, processing system 100 may be an electronics device manufacturing system. Substrate 102 can be any suitably rigid, fixed-dimension, planar article, such as, e.g., a silicon-containing disc or wafer, a patterned wafer, a glass plate, or the like, suitable for fabricating electronic devices or circuit components thereon.

Processing system 100 includes a process tool 104 (e.g., a mainframe) and a factory interface 106 coupled to process tool 104. Process tool 104 includes a housing 108 having a transfer chamber 110 therein. Transfer chamber 110 includes one or more processing chambers (also referred to as process chambers) 114, 116, 118 disposed therearound and coupled thereto. Processing chambers 114, 116, 118 can be coupled to transfer chamber 110 through respective ports, such as slit valves or the like.

Processing chambers 114, 116, 118 can be adapted to carry out any number of processes on substrates 102. A same or different substrate process can take place in each processing chamber 114, 116, 118. Examples of substrate processes include atomic layer deposition (ALD), physical vapor deposition (PVD), chemical vapor deposition (CVD), etching, annealing, curing, pre-cleaning, metal or metal oxide removal, or the like. In one example, a PVD process is performed in one or both of process chambers 114, an etching process is performed in one or both of process chambers 116, and an annealing process is performed in one or both of process chambers 118. Other processes can be carried out on substrates therein. Processing chambers 114, 116, 118 can each include a substrate support assembly. The substrate support assembly can be configured to hold a substrate in place while a substrate process is performed.

Transfer chamber 110 also includes a transfer chamber robot 112. Transfer chamber robot 112 can include one or multiple arms, where each arm includes one or more end effectors at the end of the arm. The end effector can be configured to handle particular objects, such as substrates. In some embodiments, transfer chamber robot 112 is a selective compliance assembly robot arm (SCARA) robot, such as a 2 link SCARA robot, a 3 link SCARA robot, a 4 link SCARA robot, and so on.

A load lock 120 can also be coupled to housing 108 and transfer chamber 110. Load lock 120 can be configured to interface with, and be coupled to, transfer chamber 110 on one side and factory interface 106 on another side. Load lock 120 can have an environmentally-controlled atmosphere that is changed from a vacuum environment (where substrates are transferred to and from transfer chamber 110) to or near an atmospheric-pressure inert-gas environment (where substrates are transferred to and from factory interface 106) in some embodiments. In some embodiments, load lock 120 is a stacked load lock having a pair of upper interior chambers and a pair of lower interior chambers that are located at different vertical levels (e.g., one above another). In some embodiments, the pair of upper interior chambers are configured to receive processed substrates from transfer chamber 110 for removal from process tool 104, while the pair of lower interior chambers are configured to receive substrates from factory interface 106 for processing in process tool 104. In some embodiments, load lock 120 are configured to perform a substrate process (e.g., an etch or a pre-clean) on one or more substrates 102 received therein.

Factory interface 106 can be any suitable enclosure, such as, e.g., an Equipment Front End Module (EFEM). Factory interface 106 can be configured to receive substrates 102 from substrate carriers 122 (e.g., Front Opening Unified Pods (FOUPs)) docked at various load ports 124 of factory interface 106. A factory interface robot 126 (shown dotted) can be configured to transfer substrates 102 between substrate carriers 122 (also referred to as containers) and load lock 120. In other and/or similar embodiments, factory interface 106 is configured to receive replacement parts from replacement parts storage containers 123 (not shown). Factory interface robot 126 can include one or more robot arms and can be or include a SCARA robot. In some embodiments, factory interface robot 126 has more links and/or more degrees of freedom than transfer chamber robot 112. Factory interface robot 126 can include an end effector on an end of each robot arm. The end effector can be configured to pick up and handle specific objects, such as substrates. Alternatively, or additionally, the end effector can be configured to handle objects such as process kit rings.

Any conventional robot type can be used for factory interface robot 126. Transfers can be carried out in any order or direction. Factory interface 106 can be maintained in, e.g., a slightly positive-pressure non-reactive gas environment (using, e.g., nitrogen as the non-reactive gas) in some embodiments.

Processing system 100 can include an integrated measurement and/or imaging system 101, which may be, for example, an integrated reflectometry (IR) system. Reflectometry is a measurement technique that uses measured changes in light reflected from an object to determine geometric and/or material properties of the object. Reflectance spectrometers measure the intensity of reflected light across a range of wavelengths. For dielectric films these intensity variations may be used to determine the thickness of the film. Additionally, reflectometry measurements may be used to detect CD, CD-bias, and other physical parameters related to a substrate processing outcome.

Measurement and/or imaging system 101 may be connected to factory interface 106. Alternatively, measurement and/or imaging system 101 may be connected to transfer chamber (e.g., at a location of one of the illustrated processing chambers). Alternatively, the measurement and/or imaging system 101 may be positioned in an interior of the factory interface 106 or transfer chamber 110. Measurement and/or imaging system 101 may also be a standalone system that is not connected to processing system 100. Measurement and/or imaging system 101 may be mechanically isolated from factory interface 106 and from an external environment to protect measurement and/or imaging system 101 from external vibrations. In some embodiments, measurement and/or imaging system 101 and its contained components may provide analytical measurements (e.g., thickness measurements) that may provide a profile across a surface of a substrate, such as a thickness uniformity profile, a particle count profile, a CD profile, a CD uniformity profile, an optical constant profile, a material property profile, and so on. Measurement and/or imaging system 101 may provide feedback to a user regarding the uniformity profile. Measurement and/or imaging system 101 may be an assembly that has the ability to measure film thicknesses, CD, CD-bias, optical properties, particle count, material properties, surface roughness, etc. across the entire substrate after it is processed in a chamber. Such metrology may be used to monitor process drift, out-of-specification film thickness, out-of-specification CD, CD-bias, etc. for etch, deposition, and/or other processes. The results of the measurement may be used to quickly correct or adjust process parameters of one or more process recipes executed on one or more process chambers to account for any determined process drift. Additionally, the results of the measurements may be used to determine when to perform maintenance on a process chamber, when to perform further testing on a substrate, when to flag a substrate as being out-of-specification, and so on. Although depicted as being connected to factory interface 106, in other embodiments, measurement and/or imaging system 101 may be a standalone reflectometry system or may be positioned at another location in or attached to processing system 100, as described above.

Factory interface robot 126 may place a substrate on a substrate transfer lift (e.g., lift pins) of measurement and/or imaging system 101. In one embodiment, the substrate transfer lift may then lower the substrate onto a substrate support such as a chuck (e.g., a vacuum chuck or electrostatic chuck) of measurement and/or imaging system 101. In other embodiments, the substrate may instead be lowered onto another type of substrate holder, such as a mechanical chuck, a magnetic chuck, or the like. Measurement and/or imaging system 101 may include various covers and a ventilation system to maintain a clean substrate and environment.

Within measurement and/or imaging system 101, the substrate holder may be translated by a linear actuator so that an edge of the substrate is centered under an optical camera. The substrate and the substrate holder may additionally be rotated by a rotation motor (actuator) and an optical camera or first sensor (e.g., an IR sensor, visible light sensor, etc.) may capture images or measurements of the edge of the substrate. Motion of the substrate holder about a rotational axis may be referred to as theta motion, motion of the substrate holder along a linear axis may be referred to as r motion, and combined motion of the substrate holder about the rotational axis and along the linear axis may be referred to as r-theta motion herein. As will be described in further detail below, the images or measurements may be analyzed to determine a center point of the substrate. Moving the substrate holder with both a linear (e.g., radial) and rotational motion allows the total size of measurement and/or imaging system 101 to be minimized while still enabling the capturing of measurements along the entire surface of the substrate. For example, the measurement and/or imaging system 101 may have a width of about 16″-17″, a length of about 23″-24″, and a height of about 25″-26″ in an embodiment. In some embodiments, an measurement and/or imaging system 101 can be implemented with two linear actuators and no rotational actuator (where motion for such as a system is referred to as X-Y motion), however, this may lead to the measurement and/or imaging system having a larger footprint than measurement and/or imaging system 101. In some embodiments, measurement and/or imaging system 101 may have the capability to measure film thicknesses, CD, CD-bias, etc. of up to about 100 substrates or more per hour, which is a substantial increase in throughput as compared to traditional optical metrology systems that measure a full surface of a substrate. For each substrate, hundreds to thousands (e.g., 3000) points on each substrate may be measured. The measurements may be used to determine uniformity profiles of the substrates. Accordingly, in embodiments measurement and/or imaging system 101 may be able to determine a uniformity profile of a substrate in a time duration between 20 seconds and 50 seconds.

A sensor (e.g., a reflectometer), e.g., a second sensor, of measurement and/or imaging system 101 may be used to make measurements of one or more target positions on the substrate as it is moved by linear actuator and rotational motor. The one or more target positions may be determined based on an algorithm or set of instructions that specifies the location of the target positions and the number of target positions to be measured. In some instances, the substrate may not be centered on the substrate holder. In such an instance, processing logic may determine coordinate transformations to transform between a coordinate system centered on the substrate holder and a coordinate system centered on the substrate. Appropriate transformations may be applied for each position to be measured on the substrate. Accordingly, as the substrate holder (and thus the substrate attached to the substrate holder) are rotated, the substrate holder (and thus the substrate) are also moved linearly according to the transformations so that the correct point on the substrate is measured.

During setup of measurement and/or imaging system 101, and/or after use (e.g., during a maintenance event), the linear actuator and the rotational motor may be calibrated to determine the location of the reflectometer in relation to the axes of motion of the linear actuator and/or the rotational motor. Additionally, the substrate holder may have an integrated reference target (or multiple integrated reference targets), which can be measured by the second sensor (e.g., reflectometer) and/or captured by the first sensor (e.g., camera) to obtain reference measurements/images. The integrated reference target(s) may be positioned on the substrate holder and/or on a stage that supports the substrate holder at a position that will not be covered by the substrate, and may rotate and/or otherwise change position as the substrate holder is rotated and/or moved. An integrated reference target may have a known thickness, which does not change over time.

In one embodiment, the measurement and/or imaging system includes multiple reference targets, which may be made of different materials. For example, one reference target may include bare silicon, and one reference target may include silicon with a silicon dioxide or other oxide or nitride layer having a known thickness. The sensor may periodically measure the thickness of the integrated reference target(s) and compare the measured thickness to the known thickness of the integrated reference target(s). If the measured thickness does not correspond to the known thickness of the target(s), then processing logic may determine that the sensor is generating inaccurate measurements. In some embodiments, a linear offset may be determined based on a determined difference between the measured thickness and the known thickness of the integrated reference target(s). Alternatively, a non-linear offset may be determined. The linear or non-linear offset may be applied to measurements in order to obtain accurate adjusted measurements of film thickness. In one embodiment, processing logic determines whether the difference between the measured thickness of the reference target(s) and the known thickness of the reference target(s) exceeds a difference threshold. If the difference is below the difference threshold, then an adjustment may be applied, as described above. If the difference is at or above the difference threshold, then the measurement and/or imaging system 101 may be scheduled for maintenance. Measurement and/or imaging system 101 may perform calibration of the second sensor (e.g., reflectometer) either between measurements, during measurements, or both to determine appropriate offsets to apply to measurements.

In one embodiment, the integrated reference target(s) may cause spectral reflections on the second sensor (e.g., reflectometer) from when it scans across the reference target while setting the stage. Processing logic can determine where the second sensor is relative to the target based on the positions (e.g., (r, theta) coordinates) at which spectral reflections are captured. A similar process may be determined for the first sensor (e.g., the camera). This can provide two coordinate systems that are both referenced by the target(s). The relationship between the first sensor coordinate system and the second sensor coordinate system can therefore be figured out through the reference target(s).

When the substrate is lowered onto and secured to the substrate holder, the center of the substrate may be offset from the center of the substrate holder. A processing device of measurement and/or imaging system 101 may determine one or more coordinate transformations between the center of the substrate and the center of the substrate holder (the center of the substrate holder corresponds to the axis of rotation about which the substrate holder rotates), and apply the one or more coordinate transformations to correct the offset, as described in greater detail below.

Processing system 100 can also include a system controller 128. System controller 128 can be and/or include a computing device such as a personal computer, a server computer, a programmable logic controller (PLC), a microcontroller, and so on. System controller 128 can include one or more processing devices, which can be general-purpose processing devices such as a microprocessor, central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device can also be one or more special-purpose processing devices such as an application specific integrated circuit (ASIC), a field programmable gate array (FPGA), a digital signal processor (DSP), network processor, or the like. System controller 128 can include a data storage device (e.g., one or more disk drives and/or solid state drives), a main memory, a static memory, a network interface, and/or other components. System controller 128 can execute instructions to perform any one or more of the methodologies and/or embodiments described herein. The instructions can be stored on a computer readable storage medium, which can include the main memory, static memory, secondary storage and/or processing device (during execution of the instructions). In embodiments, execution of the instructions by system controller 128 causes system controller to perform one or more of the methods described herein. System controller 128 can also be configured to permit entry and display of data, operating commands, and the like by a human operator. According to embodiments, the execution of the instructions by system controller 128 may cause the system controller 128 to verify calibration of one or more of a camera 208, a sensor 210, a placement of a substrate upon a chuck (e.g., substrate holder 206), or the like.

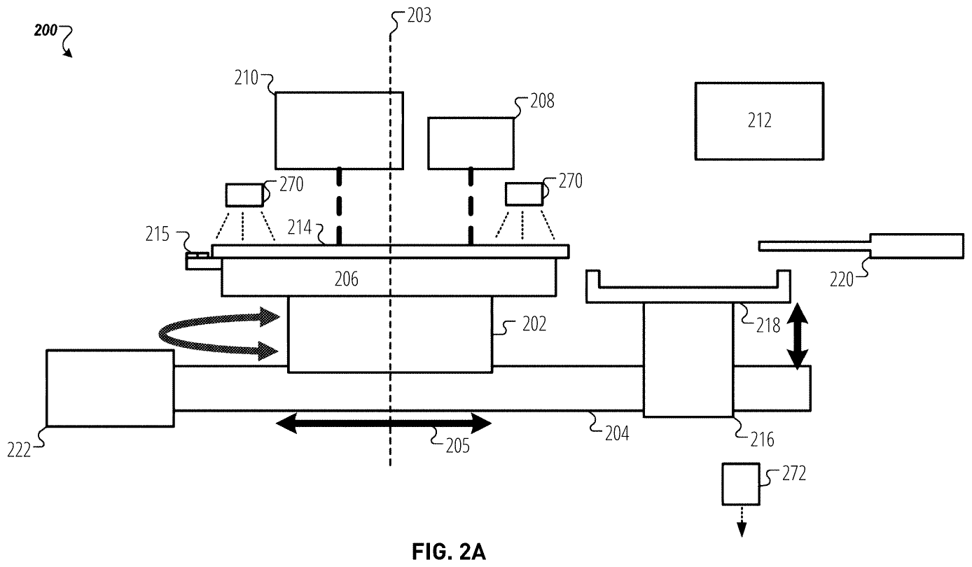

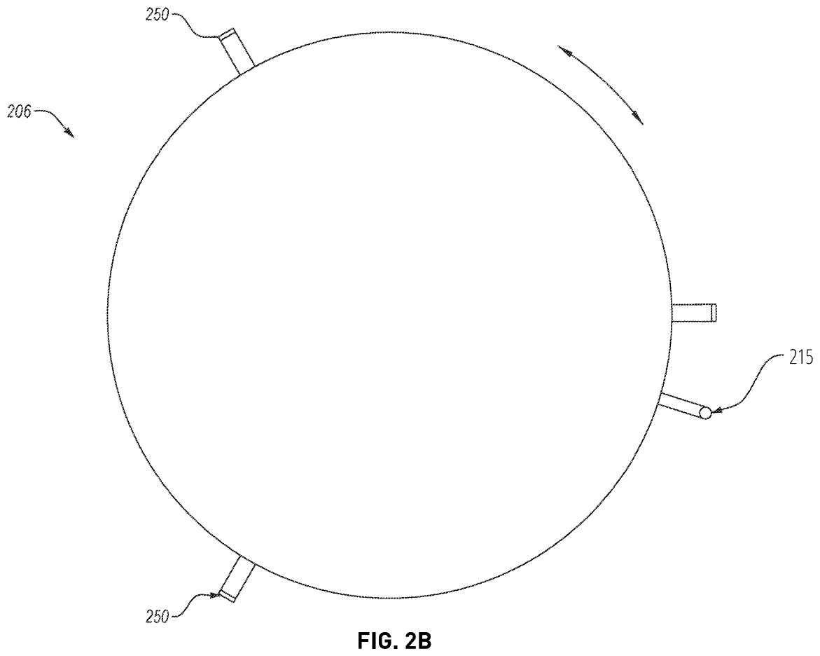

FIG. 2A is a schematic cross-sectional side view diagram of a measurement and/or imaging system 200 with a rotational actuator 202 and a linear actuator 204 according to one embodiment. Measurement and/or imaging system 200 may correspond to measurement and/or imaging system 101 of FIG. 1 in embodiments. Rotational actuator 202 may be a motor, a rotary actuator (e.g., an electric rotary actuator), or the like. Linear actuator 204 may be an electric linear actuator, which may convert rotational motion in motors into linear or straight motions along an axis. Measurement and/or imaging system 200 may include a substrate holder 206, a camera 208, a sensor 210, and a processing device 212.

Substrate holder 206 may be a chuck such as a vacuum chuck, an electrostatic chuck, a magnetic chuck, a mechanical chuck (e.g., a four jaw chuck, a three jaw chuck, an edge/ring clamp chuck, etc.) or other type of chuck. Substrate holder 206 may also be or include a plate or other surface with a substrate-shaped pocket and/or a set of pins or other features (e.g., three pins) that surround the substrate and keep the substrate from shifting relative to the substrate holder 206 during movement of the substrate holder 206. Substrate holder 206 may secure a substrate 214 (e.g., a wafer). In one embodiment, the substrate holder 206 includes an edge clamp that clamps the substrate from the edges. In one embodiment, substrate holder 206 is a vacuum chuck. In other embodiments, substrate holder 206 may be a different type of chuck such as an electrostatic chuck, a mechanical chuck, a magnetic chuck, or the like.

Rotational actuator 202 may rotate substrate holder 206 about a first axis 203. Rotational actuator 202 may be controlled by a servo controller and/or servomotor, which may allow for precise control of a rotational position, velocity and/or acceleration of the rotational actuator and thus of substrate holder 206. Substrate holder 206 may have a mass between 1.0 kilograms (kg) and 2.0 kg, which allows for rotational accelerations between 6000 deg/sec² and 14000 deg/sec². Linear actuator 204 may move substrate holder 206 linearly along a second axis 205. Linear actuator 204 may be controlled by a servo controller and/or servo motor 222, which may allow for precise control of a linear position, velocity, and acceleration of linear actuator 204, and thus of substrate holder 206.

Camera 208 may be positioned above substrate holder 206, and may generate one or more images of substrate 214 held by substrate holder 206. Camera 208 may be an optical camera, an infrared camera, or other suitable type of camera. Alternatively, camera 208 may be replaced by another type of sensor. A sensor 210 may also be positioned above substrate holder 206, and may measure at least one target position on the substrate at a time. Depending on a sensor type of sensor 210, the measurement may be a reflectometry measurement, an optical property measurement, a particle count measurement, a CD measurement, a roughness measurement, a surface geometry measurement, and/or other type of measurement. Camera 208 (or other sensor) and sensor 210 may be fixed in a stationary position on measurement and/or imaging system 200, while substrate holder 206 may be moved in an r-theta motion by rotation actuator 202 and linear actuator 204.

In some embodiments, due to the capability of the chuck to be moved according to an r-theta motion, outer dimensions of measurement and/or imaging system may be compact, (e.g., having dimensions between 20 inches and 28 inches in a first dimension, 22 inches and 28 in a second dimension, and 14 inches and 20 inches in a third dimension, with the first dimension, the second dimension, and the third dimension being mutually perpendicular), in comparison to an measurement and/or imaging system which moves the chuck in a rectangular (XY) motion system. In addition, by moving the chuck using an r-theta motion system, substrates can be processed (e.g., their uniformity profile can be determined) at a rate of up to 100 substrates per hour or more. In other words, processing device 212 may be able to generate thickness measurements of an entire substrate 214 and determine a uniformity profile of the substrate 214 in a time duration between 20 seconds and 50 seconds in embodiments.

In some embodiments, processing device 212 may determine, based on the one or more images or other measurements of substrate 214 generated by camera 208 or other sensor, that substrate 214 is not centered on substrate holder 206 and/or an estimate of a position of the substrate on the chuck (e.g., an estimate of the center of the substrate on the chuck). Substrate 214 may be not centered on substrate holder 206 when it is initially placed on substrate holder 206. A robot blade 220 may place substrate 214 on a transfer station 218 (e.g., on a set of lift pins or other lift mechanisms). Substrate holder 206 may be moved in a first direction along second axis 205 such that substrate holder 206 is positioned at transfer station 218. Transfer station 218 may be situated on a lift mechanism 216 (or may be a set of lift pins), which may move transfer station 218 up and down in a vertical direction (that is perpendicular to second axis 205 and parallel to first axis 203). Substrate 214 may be received by substrate holder 206 while substrate holder 206 is positioned at transfer station 218. Substrate 214 may not be centered on substrate holder 206. Substrate holder 206 may be moved in a second direction along second axis 205 until an edge of substrate 214 is detected to be at a target position by sensor 210.

The substrate holder 206 may be rotated 360 degrees, and images or other measurements (optionally referred to as edge images or circumference images) of the substrate 214 may be generated during the rotation of the substrate holder 206. One or more of the measurements and/or images may be taken with the substrate holder at different theta values, and the detected location of the edge may vary. A change in the detected edge may indicate that the substrate (which may be a circular substrate) is off center. Additionally, the determined change in the detected edge may be used to compute the amount of offset. Because the camera, sensor and stage are synchronized, a circumference image scan can be achieved in 3-6 seconds without stopping the stage in embodiments.

Edge images (e.g., image frames) may be analyzed by an image processing system. The image processing system detects the edge of the substrate and a position of a flat or notch in the substrate. In one embodiment, the measurement and/or imaging system 200 is connected to an illumination system (e.g., comprising one or more light sources such as light emitting diodes (LEDs)) that can turn on and off when camera measurements and/or sensor measurements (e.g., spectrometer measurements) are collected. In one embodiment, the image processing system corrects for illumination non-uniformity and finds a boundary of the wafer edge. The edge positions for each image frame may be input into a circle fitting least-squares optimization algorithm. A notch (or flat) angle may be determined by combining the angle of the image with the most probable notch or flat candidate and the position of the notch or flat within the image. The fitted circle may be the center of the substrate, and the notch angle may be the angular offset.

In one embodiment, in addition to or instead of generating images of an edge of the substrate, a camera generates images of features (e.g., alignment features) on the surface of the substrate. The features may have known positions on the substrate, and may be used to determine a center of the substrate in embodiments. In some embodiments, an initial estimate of a center of the substrate is determined based on images of an edge of the substrate, and a refined or improved estimate of the center of the substrate is determined based on images of the features on the surface of the substrate.

In one embodiment, the parameters (r, theta) determine the offset of the substrate relative to the stage. With these parameters, the motion system can create forward and inverse transformations that converts (r, theta) coordinates of the stage to (r, theta) coordinates of the substrate. The motion system can then compute trajectories in the space of the substrate while sending commands to move the motors attached to the substrate holder 206. In one embodiment, the motion system can compute trajectories in an arbitrary space because it runs a real-time control software that is connected to the motion drives of the linear actuator and the rotational actuator (e.g., through an EtherCAT network). Controller 212 may compute the corrected trajectory and transmit commanded positions to the motion drives in real-time (e.g., at a 1 kHz rate).

In some embodiments, additional calibrations are performed to determine one or more of the following:
1. A camera stage/chuck origin defined by the stage/chuck center of rotation;
2. A camera misalignment with the stage/chuck center of rotation (or a verification that the camera misalignment is within an error threshold);
3. A camera mounting error;
4. A boresight correction between the sensor and the camera or an IR sensor (or a verification that a boresight misalignment is within an error threshold); and/or
5. One or more additional calibrations to address, for example, tip, tilt and/or wobble.

The calibrations may be used to compute a sensor-stage origin and transformations applied to camera measurements and/or sensor measurements. The calibrations may ensure that the sensor measurements and/or camera measurements are accurate with respect to absolute substrate coordinates. Optics heads of the sensor (e.g., reflectometer) and the camera may have adjustments to place them approximately on a center of the rotation axis (e.g., center of the chuck) in embodiments. Additionally, alignment algorithms can add additional accuracy to the measurement position beyond mechanical adjustment tolerances.

In some embodiments, a sensor such as an IR sensor, laser sensor or other light sensor may be used to detect the substrate edge in addition to, or instead of, a camera 208. The IR sensor, laser sensor or other light sensor may include one or more light source or emitter and one or more detector, or one or more light source/detector and one or more mirror. In one embodiment, while no substrate is interposed between a light emitter (e.g., a laser, IR emitter or other light emitter) and the detector, or between a source/detector and the mirror, then no substrate is detected by that detector. However, once the substrate is interposed between a light source and detector, or between a source/detector and a mirror, a beam is broken and the substrate is detected. The r-theta coordinates accompanied by data on whether or not the substrate was detected at multiple r-theta coordinates can be used to determine that the substrate is off center and/or an amount of offset. In embodiments, a single light source and detector pair or a single light source/detector and mirror pair are used. Alternatively, multiple light source and detector pairs or multiple light source/detector and mirror pairs may be used. The multiple light source and detector pairs or light source/detector and mirror pairs may be arranged in a detection array in embodiments. If multiple light source and detector pairs or light source/detector and mirror pairs are used, then these pairs may be arranged such that they provide a light curtain. The light curtain may provide multiple data points for detection of the substrate.

In some embodiments, the substrate includes a notch and/or a flat. The images from camera 208 and/or the sensor measurements from a sensor (e.g., an edge sensor such as an IR or laser sensor) may be used to determine a location of a flat and/or notch. X-Y positions may be determined on the substrate based on the determined location of the flat or notch. The X-Y positions may be translated into r-theta positions, and r-theta positions may be translated into X-Y positions.

In some embodiments, the rotation of substrate holder 206 by rotational actuator 202 for measurement of a target position causes an offset between a field of view of sensor 210 and the target position on substrate 214 due to substrate 214 not being centered on substrate holder 206. In this case, linear actuator 204 may move substrate holder 206 linearly along the second axis to correct the offset. Then, sensor 210 may measure target positions on substrate 214. Once measurements of all target points on the substrate are measured, processing device 212 may determine a uniformity profile across the surface of substrate 214 based on the measurements.

The motion system of the measurement and/or imaging system 200 (e.g., the linear actuator 204 and the rotational actuator 202) may be synchronized with the camera 208 and/or sensor 210, such as through digital trigger signals sent over an EtherCAT network. Drives of the motion system may be connected to a real-time control server through an EtherCAT network, for example. The network enables the linear actuator 204 and/or rotational actuator 202 to receive and act on commands at a rate of up to 1 kHz in embodiments. The control network enables processing logic to transform the coordinates and path of measurements on the substrate.

In some embodiments, processing device 212 may determine one or more coordinate transformations between a center of substrate holder 206 (corresponding to first axis 203 about which substrate holder 206 rotates) and a center of substrate 214 that are applied during the rotation of substrate holder 206 to correct for the offset.

In some embodiments, in order to identify the center of substrate 214, sensor 210 may identify a number of points on an edge of substrate 214 (either via measurements or via images from camera 208), and fit those points to a circle using one or more techniques, such as using a regression analysis fitting technique. In other words, the edge positions for each image may be fed into optimization circle fitting algorithm to determine a circle. A notch angle may be found by combining an angle of the image with a most-probable notch candidate and the position of the notch within the image. The fitted circle is indicative of the center of substrate 214, and the notch angle is indicative of the angular offset.

In some embodiments, in order to identify the center and orientation of substrate 214 with higher accuracy, sensor 210 may measure positions of a number of substrate alignment targets via images from camera 208. Substrate alignment targets may include substrate marks, patterns, lines, edges, corners, and/or the like. One or more training images of substrate alignment targets may be stored on processing system 100. Images of the substrate alignment targets may be captured and compared with training images to determine translation. Embodiments can determine translation with sub-pixel accuracy by image registration algorithms using techniques such as fast Fourier transform (FFT) methods or convolutional neural network (CNN) deep learning methods. The image registration translation between substrate alignment targets and training images form position measurements of alignment targets. The position measurement of multiple substrate alignment targets may be used to fit a coordinate transformation giving additional accuracy. The measurements may be combined using a fitting algorithm (e.g. least squares) to refine the estimate of substrate center and orientation.

Some embodiments may identify substrate center and orientation with edges and a notch. Some embodiments may identify substrate center and orientation with substrate alignment targets. Some embodiments may identify substrate center and orientation in two steps with step one finding edges and notch; and step two finding substrate alignment targets.

In one embodiment, the sensor 210 and camera 208 (or other sensor) are mounted to a structure that is in turn mounted to a plate. The chuck and actuators may also be mounted to the plate. Thus, the entire system including the moving parts (e.g., chuck, actuators, etc.) and the measurement devices (e.g., camera and sensor) may all be mounted to the same plate, which is isolated from an external environment. This provides vibration isolation to the sensors as well as to the chuck from an external environment (e.g., a factory interface), and improves accuracy of measurements.

In one embodiment, one or more integrated reference targets 215 (also referred to herein as a calibration target, or pin) are attached to one end of the substrate holder 206. In one embodiment, the one or more integrated reference targets 215 include a test surface that includes at least a silicon reference target and a silicon dioxide reference target. Other types of reference targets may also be used, which may include a bare reference target of a material other than silicon and of a coated reference target that includes a base material (e.g., silicon) and a layer of another material such as an oxide or nitride (e.g., silicon dioxide, metal oxide, metal nitride, etc.). The one or more integrated reference targets 215 may be used to maintain calibration of sensor 210. In one embodiment, at least one of the one or more integrated reference targets 215 includes a coating (e.g., of silicon dioxide) having a known thickness, optical property or properties, material property or properties, particle count, etc. Sensor 210 may periodically measure a thickness and/or other property of the coating on the integrated reference target 215. The measured thickness and/or other property may then be compared to the known thickness and/or other property of the coating. If the measured thickness and/or other property does not match the known thickness and/or other property, then a determination may be made that the sensor 210 is not correctly calibrated. In one embodiment, a difference between a measured thickness and a known thickness is determined. The difference may then be compared to one or more difference thresholds. If the difference is less than a difference threshold, then an adjustment factor may be determined, and that adjustment factor may be added to future measurements of the sensor 210. If the difference is greater than the difference threshold, then maintenance of the sensor 210 may be scheduled. Similar computations may be performed for other measured and known properties of the film on the reference target.

In one embodiment, the one or more integrated reference targets 215 include a calibration target at a fixed position on the substrate holder 206. The calibration target may be a bare metal or silicon target. In one embodiment, the calibration target is a stainless steel target. The calibration target may cause spectral reflections on the sensor 210 when it has a first particular position relative to the sensor 210 (e.g., when it is directly beneath the sensor 210) and/or may cause spectral reflections on the camera 208 when it has a second particular position relative to the camera 208. The calibration target rotates with the chuck, and can be used to locate and/or calibrate a center of a sensor head of sensor 210 relative to a center of a sensor head of camera 208. The R and theta values of the substrate holder 206 that are associated with a sensor measurement of sensor 210 that results in a spectral reflection may be used to determine where the sensor 210 is relative to the calibration target. Similarly, the R and theta values of the substrate holder 206 that are associated with a camera measurement of camera 208 that results in an image in which the calibration target is at a center of the image may be used to determine where the camera 208 is relative to the calibration target. The r-theta value associated with the spectral reflection of the sensor 210 and the r-theta value associated with the centered calibration target image of the camera 208 may together be used to determine relative positions of the camera 208 and the sensor 210. In one embodiment, Controller 212 causes the substrate holder to rotate and moves the substrate holder linearly to position the substrate holder such that the target is located and centered in an image of the camera 208. The substrate holder 206 is then translated so that the target is beneath the head of the sensor 210. This may be achieved by moving the substrate holder until a reading of the sensor 210 has a maximum value. The distance between the position of the substrate holder at which the target was in the center of images generated by the camera and the position of the substrate holder at which the target was directly beneath the sensor 210 may then be determined.

In some embodiments, IR system 200 includes one or more diffusers 270 positioned above the substrate holder 206 (and above the substrate 214 when the substrate 214 is placed on the substrate holder 206). The one or more diffusers 270 may flow a gas (e.g., clean dry air, nitrogen, and/or another gas) towards the substrate 214 to prevent particles from migrating onto the substrate 214. The diffusers 270 may flow the gas toward the substrate at any angle, such as at a 90 degree angle, at an obtuse angle and/or at an acute angle. In some embodiments, the IR system 200 further includes an exhaust 272 to exhaust gas (e.g., the gas output by the diffuser(s) 270) and/or any particles moved by the gas out of an enclosure of the IR system 200. The exhaust 272 may pull particles away from the substrate 214 in embodiments.

FIG. 2B is a top-down schematic diagram of the substrate holder 206 of the IR system 200 of FIG. 2A according to one embodiment. The substrate holder 206 may rotate clockwise and/or counterclockwise about an axis at a center of the substrate holder 206 in embodiments. As shown, the substrate holder 206 includes one or more integrated reference targets 215. In one embodiment, the substrate holder 206 includes a plurality of integrated stops (e.g., wafer stops) 250 to prevent the substrate 214 from moving off of the substrate holder 206 if a holding force such as vacuum pressure or electrostatic force is lost. In one embodiment, the substrate holder 206 includes three integrated stops arranged about a periphery of the substrate holder 206. The stops 250 may be adjustable, and a distance of each of the stops from a center of the substrate holder 206 may be adjusted. In one embodiment, the stops 250 are evenly arranged about the perimeter of the substrate holder 206.

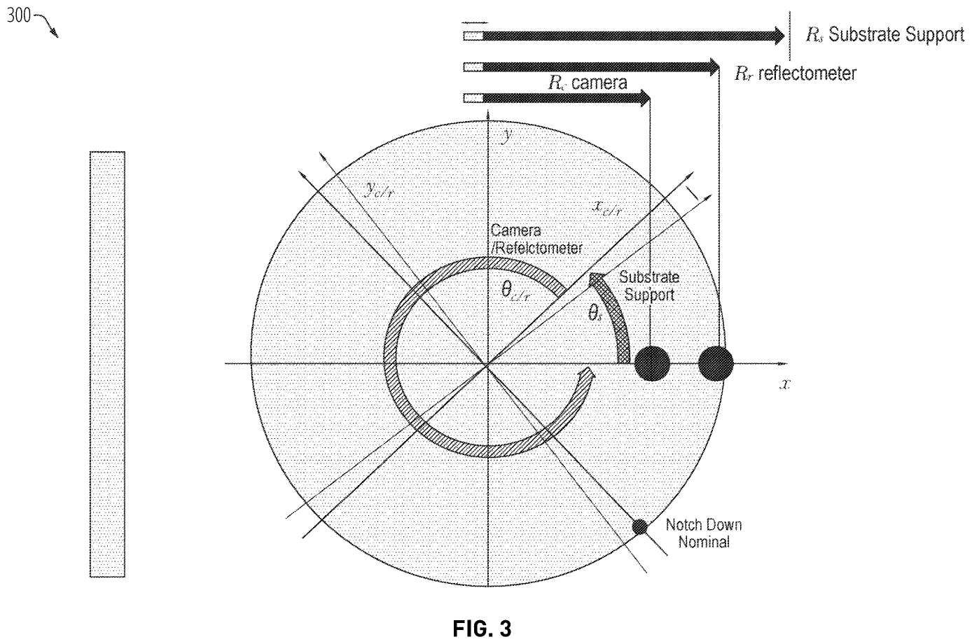

FIG. 3 is a top down schematic diagram representing rotational coordinates of a substrate holder of an IR system 300 according to one embodiment. IR system 300 may be the same as or similar to IR system 101 of FIG. 1 and/or IR system 200 of FIG. 2A. The substrate holder may be the same or similar to substrate holder 206 of FIG. 2A to FIG. 2B. The substrate holder may be positioned on a stage, which may be rotated about a rotational axis (such as first axis 203) to cause the substrate holder to also rotate. In addition, the stage may be moved about a linear axis such as second axis 205 to cause the substrate holder to also be moved. These motions allow the substrate holder, and thus any substrate secured to the substrate holder, to move according to an r-theta motion. In other words, the rotational motion allows the substrate holder to rotate by an azimuthal angle, while the linear motion allows the substrate holder to move in a radial direction, thus allowing for a full range of motion of the substrate holder and measurement of an entire surface of the substrate.

The motion system driving the stage may be synchronized with a camera and/or a reflectometer sensor through digital trigger signals. The digital trigger signals may be transmitted via a network (e.g., such as an EtherCAT network, or other type of suitable network). The network may allow for sending the trigger signals to control the motion system at a specific rate (e.g., 1 kilo-Hertz (kHz)).

The substrate holder may be positioned at an initial position defined by its radial and angular coordinates (e.g., polar coordinates): (r₀, θ₀) which can also be equivalently expressed in rectangular (Cartesian) coordinates: (x₀, y₀). The camera and the reflectometer may be located above (in a direction along the rotational axis) the substrate holder, and radial distances of R_{c} and Rᵣ, respectively. Therefore, by rotating the substrate holder from its initial angle, θ₀, and by moving the substrate holder linearly from its initial linear coordinate, r₀, the entire surface of the substrate holder, and thus the substrate secured by the substrate holder, may be scanned.

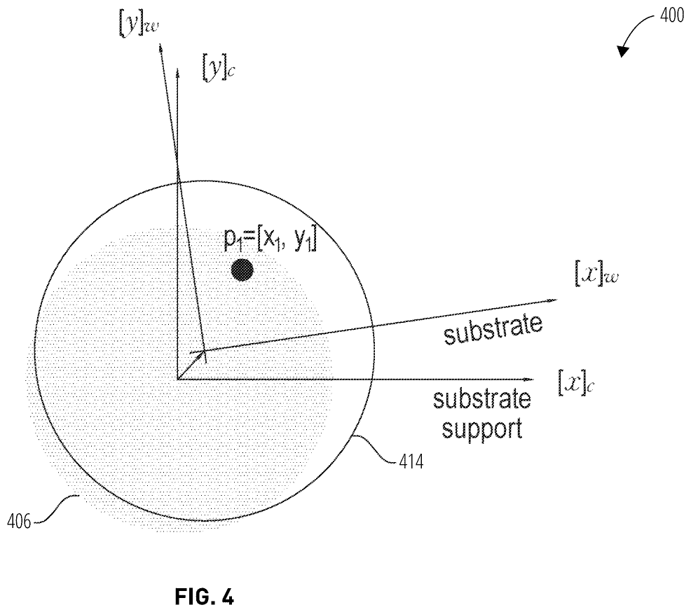

FIG. 4 is a schematic diagram of a substrate 414 placed on a substrate holder 406 according to one embodiment. Substrate holder 406 may be the same as or similar to substrate holder 206 of IR system 200 of 2. In some embodiments, there may be an error in placing substrate 414 onto substrate holder 406, such that a center of substrate 414 is offset from a center of substrate holder 406.

In one embodiment, a first coordinate system may be defined with an origin at the center of substrate holder 406: (p₀)_{c}=[0, 0, 0], where the first value corresponds to a first axis (e.g., an x-axis), the second value corresponds to a second axis perpendicular to the first axis (e.g., a y-axis), and the third value corresponds to an angle measured from the first axis towards the second axis. In addition, a second coordinate system can be defined analogously to the first coordinate system, except with the origin at the center of substrate 414: (p₀)_{w}=[0, 0, 0]. If there is an error in the placement of substrate 414, the center of substrate 414 may be expressed in the first coordinate system: [x_{offset}, y_{offset}, θ_{offset}]=[x₀, y₀, θ₀].

An arbitrary point p₁=[x₁, y₁] can be expressed in the first coordinate system as (p₁)_{c}=[x₁, y₁]_{c} and in the second coordinate system as (p₁)_{w}=[x₁, y₁]_{w}. A coordinate transformation between the first and second coordinate systems can be defined (p₁)_{c}=T_{w}^{c}(p₁)_{w}, where

$${T}_{w}^{c} = [ \begin{matrix}cos {θ}_{0} & - sin {θ}_{0} & {x}_{0} \\ sin {θ}_{0} & cos {θ}_{0} & {y}_{0} \\ 0 & 0 & 1\end{matrix} ] \qquad ( 1 )$$

An inverse transformation T_{c}^{w} can be defined between the second coordinate system and the first coordinate system such that (p₁)_{w}=T_{c}^{w}(p₁)_{c}, where

$${T}_{c}^{w} = {( {T}_{w}^{c} )}^{- 1} = [ \begin{matrix}cos {θ}_{o} & sin {θ}_{o} & - {x}_{o} cos {θ}_{o} - {y}_{o} sin {θ}_{o} \\ - s in {θ}_{o} & cos {θ}_{o} & {x}_{o} sin {θ}_{o} - {y}_{o} cos {θ}_{o} \\ 0 & 0 & 1\end{matrix} ] \qquad ( 2 )$$

Additionally, the point, p₁, may be expressed in polar coordinates (e.g., (p₁)_{w,polar}=[r₁, α₁]_{w,polar} and (p₁)_{c,polar}=[r₁, α₁]_{c,polar}) using general transformations [x, y]=[r cos θ, r sin θ] and inversely,

$$[ r , θ ] = [ \sqrt{{x}^{2} + {y}^{2}} , {tan}^{- 1} \frac{y}{x} ] .$$

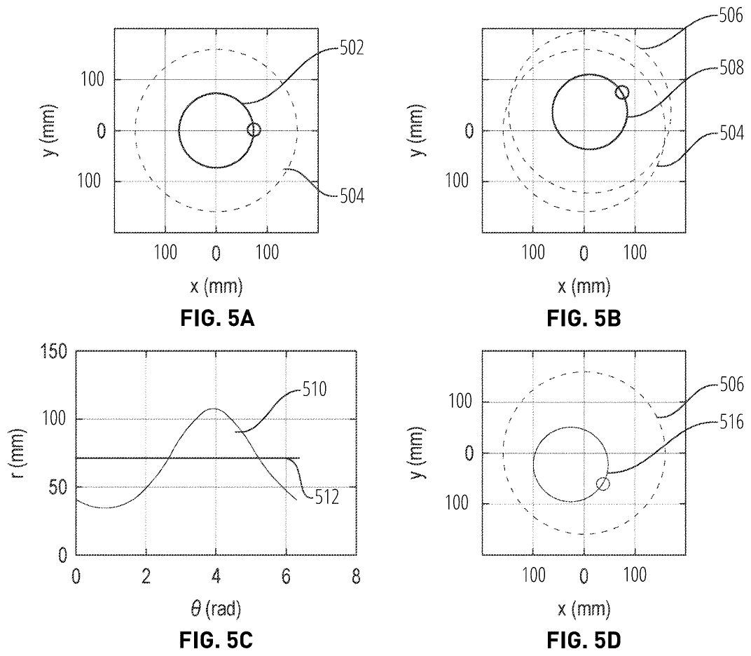

FIG. 5A to FIG. 5D are a series of graphs illustrating an example of how a substrate's placement offset on the substrate holder can be canceled out for a circular trajectory according to one embodiment. FIG. 5A shows a substrate holder 504 and a circular trajectory 502 that is to be scanned on a substrate by a fixed sensor pointed at the substrate holder 504 from above. When the substrate is placed perfectly on the substrate holder (x_{offset}, y_{offset}, θ_{offset} are all zeros), after a linear motion that places the sensor at the correct radius on the substrate, only isolated rotation of the substrate holder would allow the target scanning trajectory to be completed. FIG. 5B shows the same substrate holder 504 with a substrate 506 placed on it with exaggeratedly large offsets for illustration purposes. Circular trajectory 508 still shows the target trajectory on the substrate 506 to be scanned by the sensor. If the substrate holder 504 was to have the same motion it did for FIG. 5A, instead of scanning the target trajectory 512 shown in FIG. 5C (r=75 mm for all 0) on the substrate, it would be scanning the trajectory shown with the trajectory 510 shown in FIG. 5C, which is substantially off from the target trajectory. FIG. 5D is an illustration showing how the placement offsets can be canceled out by moving the stage linear axis in a coordinated fashion with the rotation axis. The linear axis can be moved in a way such that the sensor would be looking at what is represented with trajectory 516 on the substrate holder in FIG. 5D, causing the target circular trajectory on the substrate (as shown in FIG. 5A to FIG. 5B) to be captured by the sensor. This is because the trajectory 516 is offset from the substrate holder 504 center with an amount equal to the substrate's placement offsets on the substrate holder 504 shown in FIG. 5B, but in the opposite direction.

When substrate holders 206 or 406 are rotated about the first axis by the rotational motor, any given point on the substrate holder follows a circular trajectory (assuming that there is no simultaneous linear motion). The motion system (e.g., as described with respect to FIG. 3) can compute trajectories of an arbitrary point in the second coordinate system of the substrate while sending commands to move motors and/or actuators attached to the stage. In some embodiments, the motion system can also compute trajectories of the arbitrary space by running a real-time control software (e.g., algorithm) that may be connected and can send control signals to the motion driver through the network (e.g., an EtherCAT network).

As previously described, a motion system driving the stage may be synchronized with a camera and/or a reflectometer sensor through digital trigger signals. The digital trigger signals may be transmitted via a network (e.g., such as an EtherCAT network, or other type of suitable network). The network may allow for sending the trigger signals to control the motion system at a specific rate (e.g., 1 kilo-Hertz (kHz)). The motion software may compute the corrected trajectory and transmit, in real time, the signals to the motion driver.

Additional calibrations may be performed with respect to the center (e.g., axis of rotation) of the substrate holder (equivalently, the axis of rotation of the stage) and the camera and/or the reflectometry sensor. For example, in some embodiments, the camera may be misaligned with the axis of rotation of the substrate holder and which may benefit from correction. In some embodiments, there may be an error in the mounting of the camera which would also call for correction. In either case, transformations can be applied to the camera measurements and/or sensor measurements to correct for any misalignment. These calibrations may ensure that the sensor reflectometer measurements are accurate with respect to the coordinate system (the second coordinate system) of the substrate. Although the sensor and the camera optical heads have adjustments in order to position them approximately on the center of the rotation axis, the above-described alignment algorithms can provide additional accuracy to the measurement position beyond mechanical tolerances for adjustments.

Additional calibrations may be performed for boresight correction between the reflectometer sensor and the camera. These calibrations may compute an origin of a stage of the reflectometer sensor, and apply appropriate transformations to measurements made by the camera. These calibrations ensure that the measurements taken by the reflectometry sensor are accurate and aligned with respect to the coordinates of the substrate and/or the substrate holder (e.g., depending on how the calibrations are done). The reflectometer sensor and camera optical heads may have corresponding adjustment mechanisms, but the above-described alignment and calibration algorithms can add additional accuracy to measurements.

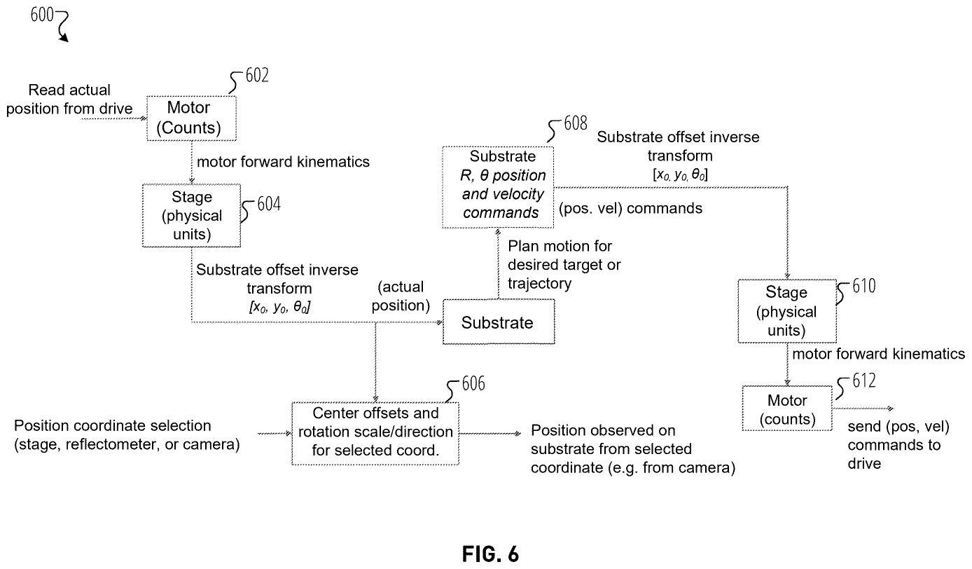

FIG. 6 is a flowchart of a method 600 of performing coordinate transformations to correct for substrate and substrate holder (also referred to herein as a chuck) offset according to one embodiment. In some embodiments, method 600 may be performed by processing logic executed by a processor of a computing device. In some embodiments, method 600 may be performed by a processing device.

Method 600 begins by reading an actual position of a stage on which the substrate holder is fixed. The stage may be rotated about a first axis by a rotational actuator (motor) and moved along a second axis by a linear actuator, such that the stage and the substrate holder can be moved in an r-theta motion. To move the stage, the motor and/or actuator(s) may be turned by discrete amounts (counts, such as encoder counts) (e.g., the motor may be turned by steps, such as one tenth, one fifth, one third, etc. of a full rotation) (block 602). This may be determined based on commands from a drive system (a motion drive system). This motion is translated into an actual motion of the stage (block 604). For example, a given step of the motor may correspond to a movement of the stage by a certain amount (rotation by some number of degrees/radians, physical linear translation by a certain distance, etc.). A coordinate transformation may be applied to correct for the center of the substrate being offset from the center of the substrate holder. Additionally, mutual offsets between the stage, the reflectometer sensor, and the camera may be calibrated, and centered with respect to a chosen point (block 606). Processing logic may determine a target trajectory, including position and velocity, for the substrate in order for the camera and the reflectometer sensor to obtain images and measurements, respectively, of the substrate (block 608). Processing logic may apply an inverse coordinate transformation to the target trajectory in order to determine a rotational and linear motion of the stage that should be applied to replicate the desired trajectory. The inverse coordinate transformation may be representative of the actual motion of the stage (block 610). Processing logic may translate the actual motion back into motor counts (block 612). The motor counts may be sent to the drive system. The method 600 then ends.

Method 600 may be repeated for each target position of the substrate to be measured.

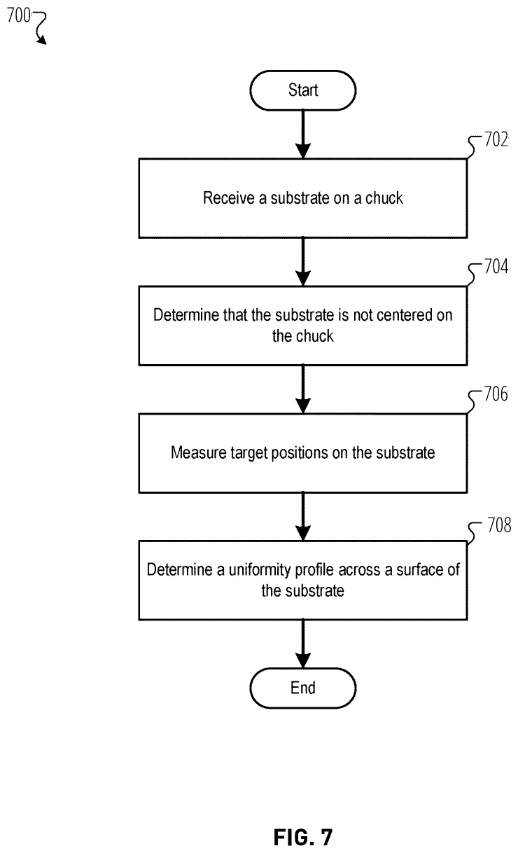

FIG. 7 is a flow chart of a method 700 of performing coordinate transformations to correct for substrate and substrate holder offset according to one embodiment. In some embodiments, method 700 may be performed by processing logic executed by a processor of a computing device. In some embodiments, method 700 may be performed by a processing device. In some embodiments, method 700 may be performed by processing system 100. In some embodiments, method 700 may be performed by measurement and/or imaging system 200 of FIG. 2A.

Method 700 begins by processing logic receiving a substrate on a substrate holder of an optical measurement device (block 702). In some embodiments, the optical measurement device may be part of processing system 100 of FIG. 1. In some embodiments, the optical measurement device may be either entirely or part of the IR system 200 of FIG. 2A. The processing logic determines that the substrate is not centered on the substrate holder (block 704) and/or a position of the substrate on the substrate holder (e.g., an offset of a center of the substrate relative to a center of the substrate holder). The amount of offsets between the substrate and the substrate holder can be designated by [x₀, y₀, θ₀]. The processing logic measures one or more target positions on the substrate (block 706). The processing logic may measure the one or more target positions using a sensor. The processing logic determines a uniformity profile across a surface of the substrate based on measurements of the one or more target positions.

In some embodiments, to measure one of the one or more target positions on the substrate, the processing logic causes the substrate holder to be rotated about a first axis. The rotation of the substrate holder about the first axis causes an offset between a field of view of the sensor and the target position due to the substrate not being centered on the substrate holder. The processing logic may correct the offset by moving the substrate holder linearly along a second axis.

In some further embodiments, the processing logic determines one or more coordinate transformation between a first center of the substrate holder and a second center of the substrate. The first center of the substrate holder corresponds to the first axis about which the substrate holder rotates. The processing logic applies at least one of the one or more coordinate transformations to the substrate holder during the rotation to correct the offset.

In some further embodiments, the processing logic identifies one or more points corresponding to an edge of the substrate and performs fitting of the one or more points of the edge of a substrate to a circle. The processing logic may perform this operation to identify the (second) center of the substrate.

In some further embodiments, the processing logic uses the uniformity as input to a machine learning model. The processing logic obtains one or more outputs of the machine learning model. In some embodiments, the one or more outputs indicate a process drift of the measurement device. The method 700 ends.

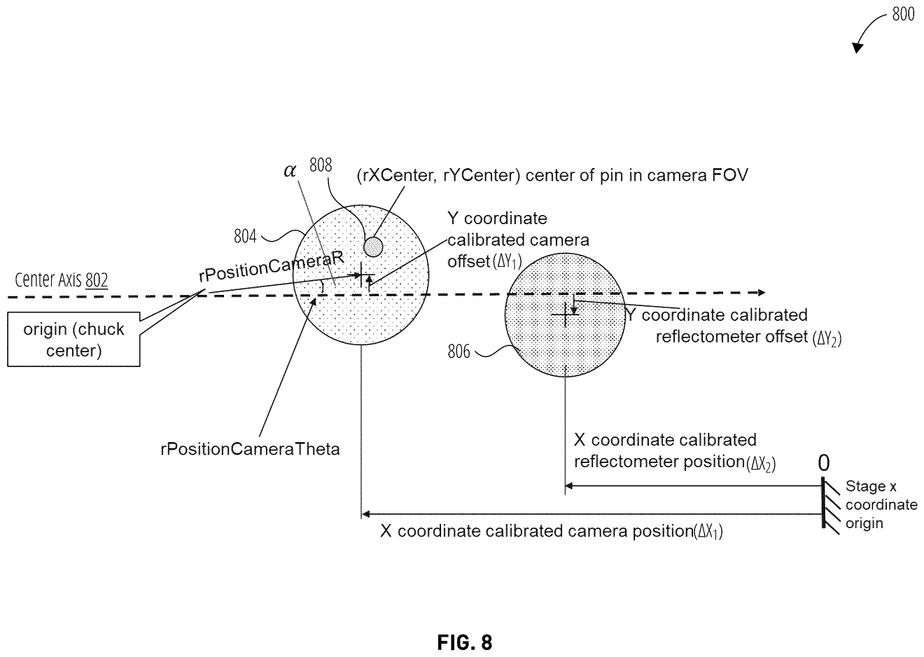

FIG. 8 is a top down schematic diagram representing rotational and/or linear offsets of a processing system 800 including a camera and a reflectometer, according to one embodiment. The processing system 800 may include some or all of the features of the processing system 100 of FIG. 1, the imaging system 200 of FIG. 2A, or the IR system 300 of FIG. 3.

According to embodiments, a stage including a chuck (also referred to herein at a substrate holder, such as the substrate holder 206 of FIG. 2A), may be capable of moving linearly via a linear actuator (e.g., linear actuator 204) along a center axis 802 (e.g., the second axis 205). The stage may also include a rotational actuator (e.g., the rotational actuator 202) that allows the stage to rotate the chuck around an axis perpendicular to the center axis 802 (e.g., the first axis 203). As such, the stage may be capable of moving the chuck in an R-theta motion across a horizontal plane (e.g., x-y plane). In some embodiments, the stage may also be capable of moving vertically (e.g., in x-y-z direction).

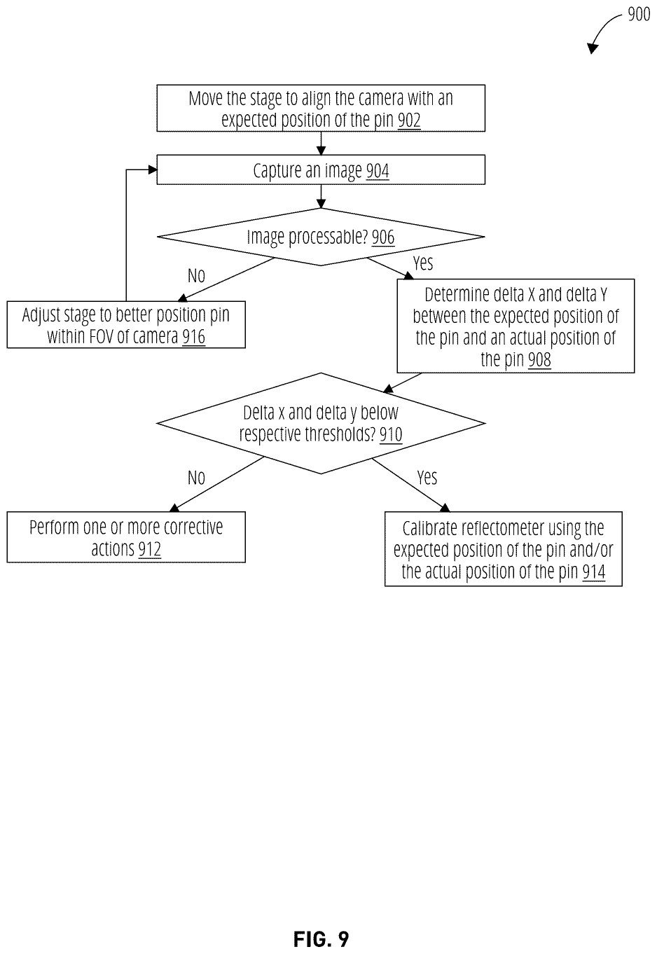

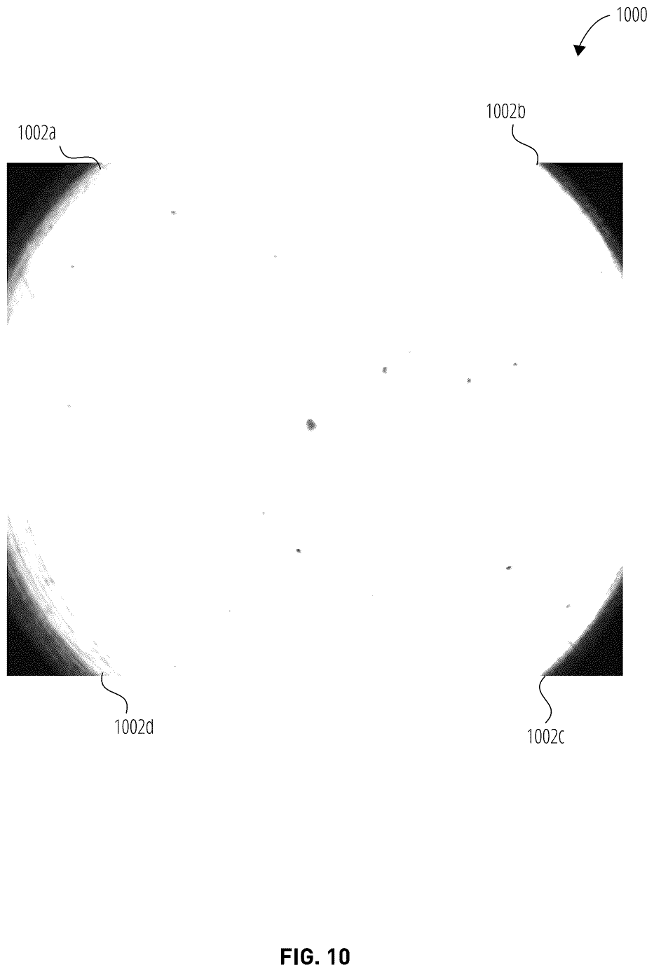

In some embodiments, the processing system 100 may calculate one or more camera offset values (e.g., cartesian coordinates) relative to the center axis 802 by capturing one or more images of a pin 808 (also referred to herein as integrated reference targets 215, or calibration target) using a fixed camera 804 (e.g., camera 208). The pin 808 may include a test surface that includes at least a first material type (e.g., silicon) and a second material type (e.g., silicon dioxide). The pin may be any other suitable calibration target, and may take various different shapes, such as a rectangular, circular, oval, square, pentagonal, octagonal, or the like. The process of determining these one or more camera offset values is discussed in more detail with respect to at least FIG. 9 and FIG. 10.

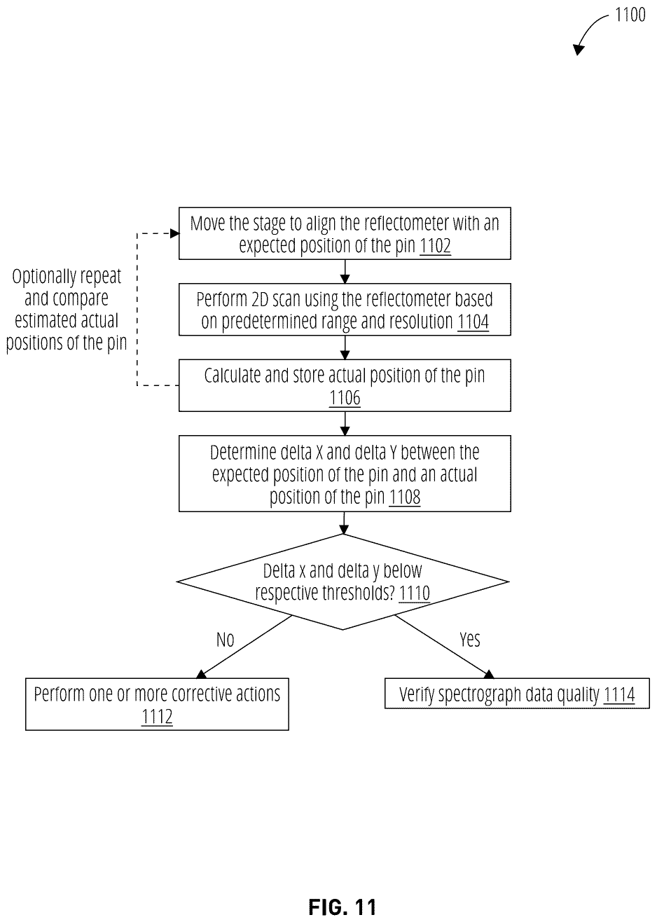

Using the one or more camera offset values, the processing system 100 may calculate one or more reflectometer offset values relative to the center axis 802 using a fixed reflectometer 806 (e.g., sensor 210). The process of determining these one or more reflectometer offset values is discussed in more detail with respect to at least FIG. 11.

FIG. 9 is a flowchart illustrating a method 900 of calibrating and/or validating a position of a camera within a processing system such as the processing system 800, according to one embodiment. In some embodiments, the method 900 may include physically positioning a stage with respect to the camera to calculate one or more camera offset values. According to embodiments, the method 900 may be performed by processing logic that includes, hardware, software, firmware, or any combination thereof. In some embodiments, the processing logic includes memory storing instructions where, upon one or more processors executing the instructions, may cause the processing logic to perform the method 900. In some embodiments, the method 900 may be performed using one or more components of the processing system 100, imaging system 200, the IR system 300, and/or the processing system 800. Other devices may perform the method 900 as described herein.

At block 902, the processing logic may move the stage of the processing system to align a camera (e.g., fixed camera 804) with an expected position of a pin (e.g, pin 808). In some embodiments, the pin may be attached to a moveable chuck of the stage and may be capable of moving in an R-Theta motion in tandem with the chuck. While the stage may move in an R-Theta motion, the expected position of the pin may be characterized as cartesian coordinates. As such, in at least some embodiments, the stage may be capable of transforming coordinates of the expected position of the pin into an R-Theta coordinate mapping. In some cases, the pin may be the same or similar to the integrated reference targets 215 as described above with respect to FIG. 2A and FIG. 2B. According to embodiments, the expected position of the pin with respect to the camera may be coordinates corresponding to a most-recently performed calibration or validation of the position of the camera. In other embodiments, the expected position of the pin with respect to the camera may be predetermined, default coordinates. In some cases, the processing system may store the expected position of the pin in memory as a starting point of the method 900. The expected position of the pin with respect to the camera may be stored either as cartesian coordinates or as R-Theta coordinates.

At block 904, the processing logic may cause the camera to capture an image. At decision block 906, the processing logic may determine whether the image is processable. According to embodiments, the image is processable if at least a portion of the pin is visible within the image. In one embodiment, the image may be processable if the image includes at least a portion of an edge of the pin. In another embodiment, the image may be processable if the image captures at least a threshold amount (e.g., 25%, 50%, etc.) of the pin. According to embodiments, the image may be processable if at least four different portions of the edge of the pin are captured by the image. In at least one embodiment, for the image to be processable, the image may include at least a portion of the substrate edge in each quadrant of the image. In embodiments where the pin is not circular (e.g., rectangular), the image may be processable if the image includes at least one corner of the pin. In at least one embodiment, the processing logic may determine that the image is not processable if the image does not capture a threshold spatial coverage (e.g., spatial area) of the pin. If the image is not processable, the processing logic may iteratively move the pin with respect to the camera and take an additional image until an image is captured that is processable. If the processing logic determines that the image is processable, the processing logic may determine camera offset values (Δx₁, Δy₁) of the camera at block 908. According to embodiments, these camera offset values may represent a drift (e.g., drift parameter) corresponding to the camera. If the processing logic determines that the image is not processable, the processing logic may adjust the stage to better position the pin within the field of view (FOV) of the camera at block 916.

At block 908, the processing logic may determine the camera offset values (Δx₁, Δy₁) of the camera. In one embodiment, these camera offset values (Δx₁, Δy₁) may represent a difference between the expected position of the pin and the actual observed position of the pin. In another embodiment, the camera offset values (Δx₁, Δy₁) may represent an overall offset between the actual position of the pin and (i) a zero-position of the stage (Δx₁) and (ii) the center axis (Δy₁).

In order to calculate the actual position of the pin, the processing logic may perform one or more image processing operations. The processing logic can employ several processes, starting with image preprocessing to enhance the contrast and reduce noise. Edge detection algorithms can then be applied to identify the pin's boundaries within the image. Once the edges are detected, contour detection methods can be used to locate the shape of the pin. Then, to determine the actual position of the pin, the processing logic may use blob detection to find a centroid of the pin or Hough transform if the pin has a circular or cylindrical shape. In some cases, perspective transformation and homography mapping can be used to convert the pixel coordinates into real-world stage coordinates. In some cases, one or more learning-based object detection models (e.g., a convolutional neural network (CNN)) can be trained to detect the pin and output its location directly. If multiple reference points (fiducials) are available in the image, the system can apply geometric transformations and coordinate transformations to determine the actual position of the pin relative to the camera. By combining the actual position of the pin relative to the camera with the current position of the stage, the actual position of the pin with respect to the stage can be determined.

At decision block 910, the processing logic may determine whether the camera offset values (Δx₁, Δy₁) fall below respective thresholds (e.g., a first threshold to compare against Δx₁, and a second threshold to compare against Δy₁). These respective thresholds may be calibrated to ensure that downstream calibration and/or verification processes can be performed correctly by the processing system. In some embodiments, these thresholds may be used to verify that a difference between the expected position of the pin and the actual position of the pin is within acceptable tolerance levels. If the camera offset values (Δx₁, Δy₁) fall below (e.g., satisfy) their respective thresholds, the processing logic may result in a position of a reflectometer (e.g., fixed reflectometer 806) to be calibrated and/or verified using one or more of the expected position of the pin or the actual position of the pin at block 914.

If one or more of the camera offset values (Δx₁, Δy₁) do not satisfy their respective threshold, the processing logic may cause one or more corrective actions to be performed at block 912. These corrective actions can include generating an alert to the user, displaying a diagnostic report that includes detected misalignment values and suggested corrective actions, such as manual re-alignment or lens adjustments, and/or scheduling a recalibration cycle. In some cases, this recalibration cycle may be an automated process that re-calibrates the expected position of the pin with respect to the camera according to current operating conditions of the processing system. For example, the coordinate system that the processing system uses to move the stage may have drifted, and the expected position of the pin may be recalibrated according to the drift. In one embodiment, to recalibrate the expected position of the pin with respect to the camera, the processing system may incrementally move the stage to capture multiple reference images, and may use these captured images to re-calculate the expected position of the pin with respect to the camera.

As used herein, the “expected position” of the pin, either with respect to the camera or a reflectometer, may refer to various initial reference points used to guide the verification processes described herein. In some cases, the “expected position” may correspond to a default starting location with respect to a center chuck line. Here, the “expected position” of the pin may be the same each time that the respective verification process is performed. In another embodiment, the “expected position” may represent the last-known or last-calibrated position of the pin. In some embodiments, the “expected position” may be derived using a predictive model based on prior offset patterns or operational history.

FIG. 10 is an exemplary image 1000 of the pin (calibration target) as described above with respect to FIG. 9, according to one embodiment. In at least some embodiments, a center of the processing system 100 may correspond to the actual position of the camera. Here, as illustrated, multiple edges 1002a-d are captured within the image 1000. Because a radius of the pin (calibration pin target) may be known, these multiple edges 1002a-d may be used calculate a center of the pin relative to the center of the image. In one embodiment, the camera offset values (Δx₁, Δy₁) may be a difference between the center of the pin and the center of the image.

To calculate the center of the pin relative to the center of the image 1000, the processing logic may first apply edge detection techniques, such as Canny edge detection or Sobel filtering, to highlight the pin's boundary. Next, the processing logic may use a contour detection algorithm to extract the curved edges corresponding to the pin. If only a portion(s) of the edge 1002 of the pin are visible, the processing logic may fit an arc or partial circle to the detected edges (also referred to as identified edges) using methods like random sample consensus or least-squares fitting. This curve may also be determined using the known radius of the pin. Using the best-fit curve, the processing logic may calculate the estimated center of the pin. Then, to find the center of the pin relative to the center of the image, the processing logic may calculate the pixel coordinates of both points: the estimated circle center (rXCenter, rYCenter) and the image center (X_img, Y_img), which is half of the image width and height. Then, the offset between the centers of the pin and image can be determined by subtracting the image center coordinates from the pin center coordinates, i.e., Δx₁=rXCenter−X_img, Δy₁=rYCenter−Y_img.

FIG. 11 is a flowchart illustrating a method 1100 of calibrating and/or validating a position of a reflectometer or other sensor within a processing system such as the processing system 800, according to one embodiment. In some embodiments, the method 1100 may include physically positioning a stage with respect to the reflectometer to calculate one or more reflectometer offset values. In some embodiments, the method 1100 may include physically positioning a stage with respect to the camera to calculate one or more camera offset values. According to embodiments, the method 1100 may be performed by processing logic that includes, hardware, software, firmware, or any combination thereof. In some embodiments, the processing logic includes memory storing instructions where, upon one or more processors executing the instructions, may cause the processing logic to perform the method 1100. In some embodiments, the method 1100 may be performed using one or more components of the processing system 100, imaging system 200, the IR system 300, and/or the processing system 800. Other devices may perform the method 1100 as described herein.

At block 1102, the processing logic may move the stage of the processing system to align the reflectometer (e.g., sensor 210) with an expected position of a pin (also referred to as a calibration pin target) (e.g., pin 808). In some embodiments, the pin may be attached to a moveable chuck of the stage and may be capable of moving in an R-Theta motion in tandem with the chuck. While the stage may move in an R-Theta motion, the expected position of the pin may be characterized as cartesian coordinates. As such, in at least some embodiments, the stage may be capable of transforming the cartesian coordinates of the expected position of the pin into an R-Theta coordinate mapping, or vice-versa. In some cases, the pin may be the same or similar to the integrated reference targets 215 as described above with respect to FIG. 2A and FIG. 2B. In other embodiments, the pin may be a different fixture than the integrated reference targets 215 and may be attached to the chuck and rotate with the chuck. According to embodiments, the expected position of the pin with respect to the reflectometer may be coordinates corresponding to a most-recently performed calibration or validation of the position of the reflectometer. In other embodiments, the expected position of the pin with respect to the reflectometer may be predetermined, default coordinates. In some cases, the processing system may store the expected position of the pin in memory as a starting point of the method 1100. The expected position of the pin with respect to the reflectometer may be stored either as cartesian coordinates or as R-Theta coordinates.

At block 1104, the processing logic may perform a 2-dimensional (2D) scan using the reflectometer based on a predetermined range and resolution. The 2D scan may be performed by iteratively adjusting the pin (calibration target) with respect to the reflectometer to different positions and scanning with the reflectometer. These different positions may be a grid of additional chuck positions that are based on the expected position of the pin when aligned with the reflectometer. This grid may be a 2D grid that the processing logic uses to perform the 2D scan. In other words, the 2D scan may be performed by iteratively alternating between moving the chuck to one of the additional chuck positions and generating a spectral frame using the reflectometer until each of the additional chuck positions has a respective spectral frame. By doing so, the processing logic can capture, via the reflectometer reflectance measurements at each position of the stage, a spectral frame for each of the respective additional chuck positions, and can generate a reflectivity map (i.e., using the respective spectral frames) representing surface characteristics of the pin. In at least one embodiment, a Gaussian fit may be applied to values of the spectral frames to generate the reflectivity map. The 2D scan may be designed with enough range to encompass both the pin and at least a portion of a background (i.e., a non-pin, non-chuck surface that returns a distinct reflectivity strength). This may allow the processing logic to find an edge of the pin.

At block 1106, the processing logic may calculate and store an actual position of the pin. The processing logic may know the physical composition, pattern, and shape of the pin. The processing logic may compare the known physical properties of the pin to the gathered reflectometer scan results to determine the actual position of the pin with respect to the reflectometer. In some cases, the processing logic may use a matching and optimization process to determine the actual position of the pin. For example, the processing logic may first align the collected reflectivity measurements with the expected reflectance profile of the pin which may be derived from its material composition, surface roughness, and geometry. By analyzing variations in reflectance intensity and distribution, the processing logic can identify key surface features of the pin such as edges, curvature, or distinct reflectance patterns. Next, the processing logic can apply pattern matching algorithms to align the observed 2D scan with a simulated or reference reflectance model. Techniques such as template matching, cross-correlation, or iterative closest point (ICP) algorithms can be used to refine the estimated location by minimizing differences between the measured and expected reflectance profiles. If the pin has distinct edges or known geometric features (e.g., a circular or cylindrical shape), edge fitting algorithms such as Hough Transform, least-squares circle fitting, or the like can help pinpoint the center relative to the scan data.

Optionally, the processing logic may repeat the operations of blocks 1102, 1104, 1106 and compare the estimated or otherwise calculated actual positions of the pin corresponding to each iteration. In at least some embodiments, estimating the actual position of the pin multiple times may facilitate a better overall estimation of the actual position of the pin with respect to the reflectometer.

At block 1108, after the actual position of the pin is determined, the processing logic may determine the reflectometer offset values (Δx₂, Δy₂) of the reflectometer. According to embodiments, the reflectometer offset values may represent drift (e.g., drift parameter) corresponding to the reflectometer. In one embodiment, these reflectometer offset values (Δx₂, Δy₂) may represent a difference between the expected position of the pin with respect to the reflectometer and the actual position of the pin with respect to the reflectometer. In another embodiment, the camera offset values (Δx₂, Δy₂) may represent an overall offset between the actual position of the pin with respect to the reflectometer and (i) a zero-position of the stage (Δx₂) and (ii) the center axis (Δy₂).

At decision block 910, the processing logic may determine whether the reflectometer offset values (Δx₂, Δy₂) fall below respective thresholds (e.g., a third threshold to compare against Δx₂, and a fourth threshold to compare against Δy₂). These respective thresholds may be calibrated to ensure that downstream calibration and/or verification processes, such as a spectrograph data quality verification, can be performed correctly by the processing system. In some embodiments, these thresholds may be used to verify that a difference between the expected position of the pin with respect to the reflectometer and the actual position of the pin with respect to the reflectometer is within acceptable tolerance levels. If the reflectometer offset values (Δx₂, Δy₂) fall below (e.g., satisfy) their respective thresholds, the processing logic may cause that a spectrograph data quality verification process is performed at block 1114.

If one or more of the reflectometer offset values (Δx₂, Δy₂) do not satisfy their respective threshold, the processing logic may cause one or more corrective actions to be performed at block 1112. These corrective actions can include generating an alert to the user, displaying a diagnostic report that includes detected misalignment values and suggested corrective actions, such as manual re-alignment, and/or scheduling a recalibration cycle. In some cases, this recalibration cycle may be an automated process that re-calibrates the expected position of the pin with respect to the reflectometer according to current operating conditions of the processing system. This re-calibration may determine anew an offset between the reflectometer position and (i) the zero-position of the stage (Δx₂) and (ii) the center axis (Δy₂). For example, the coordinate system that the processing system uses to move the stage may have drifted, and the expected position of the pin with respect to the reflectometer may be recalibrated according to the drift. In one embodiment, to recalibrate the expected position of the pin with respect to the reflectometer, the processing system may incrementally move the stage to capture multiple reference spectrographic data (e.g., reflectometer data), and may use this captured data to re-calculate the expected position of the pin with respect to the reflectometer. In another embodiment, the expected position of the pin with respect to the reflectometer may be updated after re-calibrating a camera of the processing system.

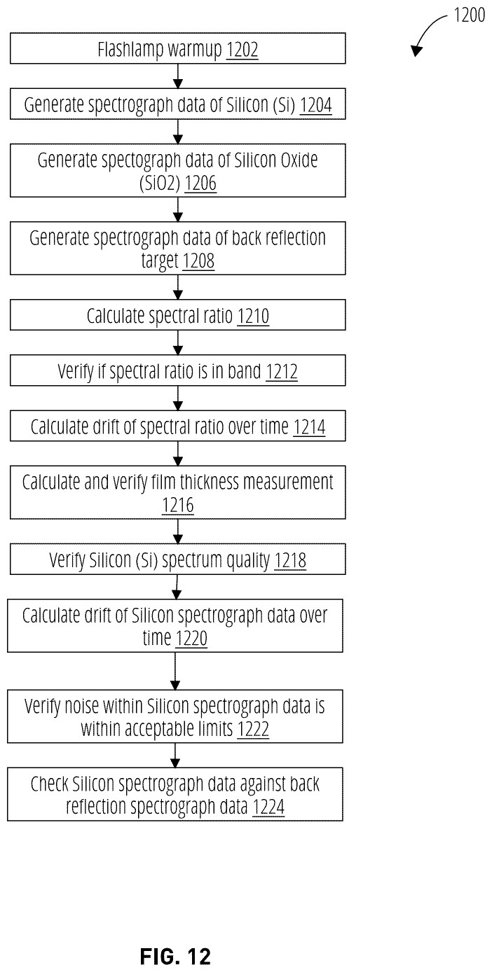

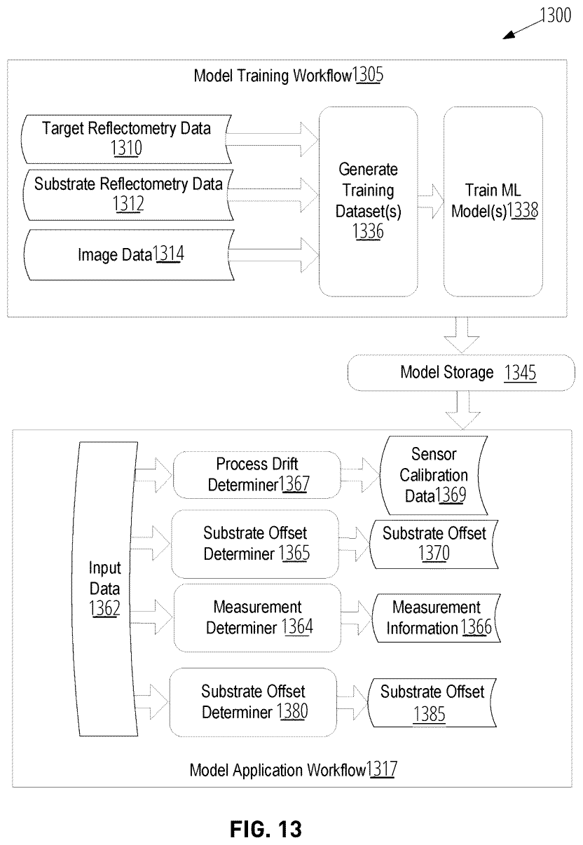

FIG. 12 is a flowchart illustrating a method 1200 of verifying quality of spectrograph data generated using a reflectometer of a processing system, such as the processing system 800, according to one embodiment. In some embodiments, the method 1200 may include physically positioning one or more reference targets (e.g., integrated reference targets 215) underneath the reflectometer to generate spectrograph data, which spectrograph data can then be analyzed using one or more stored reference datasets. According to embodiments, the method 1200 may be performed by processing logic that includes hardware, software, firmware, or any combination thereof. In some embodiments, the processing logic includes memory storing instructions where, upon one or more processors executing the instructions, may cause the processing logic to perform the method 1200. In some embodiments, the method 1200 may be performed using one or more components of the processing system 100, imaging system 200, the IR system 300, and/or the processing system 800. According to embodiments, one or more of the operations described with respect to the method 1200 may be performed using the model training workflow 1305 and the model application workflow 1317 described below with respect to FIG. 13. Other devices may perform the method 1200 as described herein.

At block 1202, the processing logic may optionally warm up a flash lamp of the reflectometer. Warming up the flash lamp of a reflectometer before gathering spectrograph data may be useful because it stabilizes the lamp's output intensity and spectral characteristics. When first powered on, a flash lamp can exhibit fluctuations in brightness and spectral distribution due to temperature variations in the electrodes and gas medium. Allowing the lamp to warm up can help ensure a more consistent and repeatable light output, reducing measurement variability and improving the accuracy of gathered spectrograph data. In some embodiments, warming up the flash lamp may include allowing the flash lamp to run until it reaches a steady state. In some cases, the flash lamp may be run or otherwise operated for approximately 300-400 pulses before reaching a steady state.

At block 1204, the processing logic may acquire spectrograph data corresponding to a silicon reference target. According to embodiments, this may involve positioning the silicon reference target (e.g., part of the integrated reference targets 215) underneath the reflectometer (e.g., sensor 210). Once the silicon reference target is positioned underneath the reflectometer, the processing logic may cause the reflectometer to gather spectrograph data corresponding to a first wavelength range. In some embodiments, this first wavelength range may include at least approximately 200-800 nm. In one embodiment, this first wavelength range may include any wavelengths below approximately 1100 nm. In embodiments where the spectrograph data is to be used to verify subsurface imaging or defect analysis, wavelengths between approximately 1100-2500 nm may be used within the first wavelength range. In at least some embodiments, spectrograph data includes data points for different wavelengths within the first wavelength range. For example, if the first wavelength range is 200-800 nm, the processing logic may gather a total of approximately 1201 data points using the reflectometer. The spectrograph data corresponding to the silicon target may be referred to as “S1” (sample #1).

In some cases, downstream processing may truncate the sample S1 such that the sample S1 correlates to a subset of the first wavelength. For example, in some cases, the sample S1 may be truncated in order to correspond to a wavelength range of 300-800 nm. Here, data points corresponding to wavelengths between 200-300 nm may be removed from the sample S1.

In at least some embodiments, the processing logic may collect multiple samples S1 for downstream noise monitor calculation. For example, in at least some embodiments, the processing logic may collect approximately 500 samples S1 or more (e.g., at least five samples S1, or, in other worse, at least five sets of spectrograph data each corresponding to the first material). Each of these samples S1 may be denotes as S1₁, S1₂, . . . , S1_{N}, where N is the number of collected samples S1. In other embodiments, the processing logic may collect less than 500 samples S1 for downstream noise monitor calculations. While the above description uses multiple samples S1 for the downstream noise monitor calculation, multiple samples S2 (described below) may be additionally or alternatively used for the downstream noise monitor calculation.

At block 1206, the processing logic may acquire spectrograph data corresponding to a silicon dioxide reference target. According to embodiments, this may involve positioning the silicon dioxide reference target (e.g., part of the pin 808 or integrated reference targets 215) underneath the reflectometer (e.g., sensor 210). Once the silicon dioxide reference target is positioned underneath the reflectometer, the processing logic may cause the reflectometer to gather spectrograph data corresponding to a second wavelength range. In one embodiment, the second wavelength range may be a same wavelength range as the first wavelength range. In another embodiment, the second wavelength range may be a different wavelength range than the first wavelength range. In some embodiments, this second wavelength range may include at least approximately 200-800 nm. In one embodiment, this second wavelength range may include any wavelengths below approximately 1100 nm. In embodiments where the spectrograph data is to be used to verify subsurface imaging or defect analysis, wavelengths between approximately 1100-2500 nm may be used within the second wavelength. In at least some embodiments, spectrograph data includes data points for different wavelengths within the second wavelength range. For example, if the second wavelength range is 200-800 nm, the processing logic may gather a total of approximately 1201 data points using the reflectometer. The spectrograph data corresponding to the silicon dioxide target may be referred to as “S2” (sample #2).

In some cases, downstream processing may truncate the sample S2 such that the sample S2 correlates to a subset of the second wavelength. For example, in some cases, the sample S2 may be truncated in order to correspond to a wavelength range of 300-800 nm. Here, data points corresponding to wavelengths between 200-300 nm may be removed from the sample S2.

At block 1208, the processing logic may acquire spectrograph data corresponding to a back reflection target. According to embodiments, this back reflection target may be an ‘empty space’ where there is no reflection from the bottom. This may involve positioning the stage such that no reference targets are directly underneath the reflectometer (i.e., positioning the stage such that a back reflection target is directly underneath the reflectometer). Then, the processing logic may cause the reflectometer to gather spectrograph data corresponding to a third wavelength range. In one embodiment, the third wavelength range may be a same wavelength range as one or more of the first or second wavelength ranges. In at least one embodiment, the third wavelength range may be a different wavelength range than one or more of the first and second wavelength ranges. In some embodiments, this third wavelength range may include at least approximately 200-800 nm. In one embodiment, this third wavelength range may include any wavelengths below approximately 1100 nm. In embodiments where the spectrograph data is to be used to verify subsurface imaging or defect analysis, wavelengths between approximately 1100-2500 nm may be used within the third wavelength. In at least some embodiments, spectrograph data includes data points for different wavelengths within the third wavelength range. For example, if the third wavelength range is 200-800 nm, the processing logic may gather a total of approximately between 500-2000 data points using the reflectometer. In other embodiments, any suitable number of data points may be gathered. The spectrograph data corresponding to the back reflection target may be referred to as “S3” (sample #3).

At block 1210, the processing logic may calculate or otherwise determine spectral ratio data between S1 and S2. This spectral ratio may be referred to as S21Ratio (sample 21Ratio). To determine S21Ratio, the processing logic may perform the following:

$$for each indexed data point i , S 21 Ratio ( i ) = \frac{S 2 ( i )}{S 1 ( i )} .$$

At block 1212, the processing logic may determine whether spectral ratio drift (also referred to herein as RatioDrift) is detected. Spectral ratio drift may refer to a change in the ratio between data points of S2 and S1 (e.g., spectral intensities at different wavelengths) over time. Drift in the calculated S21Ratio over time may be caused by a number of factors, including but not limited to lamp intensity drift, reflectometer sensitivity drift, the aging of components of the reflectometer, temperature variations, humidity effects, or the like. To determine whether S21Ratio has experienced spectral ratio drift, S21Ratio may be compared to a historical S21Ratio (herein referred to as PrevS21Ratio). PrevS21Ratio may be a most-recently determined historical S21Ratio (e.g., a most recent historical execution of the method 1200). In another embodiment, PrevS21Ratio may be a historical S21Ratio that was determined during or directly after a most recent calibration of the reflectometer or processing system. To determine the spectral ratio drift, the processing logic may perform the following:

$$for each indexed data point i , RatioDrift ( i ) = \frac{S 21 Ratio ( i )}{Prev S 21 Ratio ( i )} .$$

According to embodiments, the processing logic may determine an average drift ratio value by comparing data points of RatioDrift. The average drift ratio value may be compared to one or more of a first warning threshold or a first fault threshold. In at least one embodiment, the processing logic may determine multiple average drift ratio values that each correspond to a different wavelength subrange. For example, the processing logic may determine at least a first average spectral ratio drift value that corresponds to a first wavelength subrange (e.g., 300-400 nm), a second average spectral ratio drift value that corresponds to a second wavelength subrange (e.g., 400-600 nm), and a third average spectral ratio drift value that corresponds to a third wavelength subrange (e.g., 600-800 nm). Here, each of the first, second, and third average spectral ratio drift values may be compared to one or more of the first warning threshold or the first fault threshold. In another embodiment, any of the first, second, and third average spectral ratio drifts may be compared to a different warning or fault threshold. If any average spectral drift value exceeds their respective warning threshold, one or more corrective actions may be performed, such as generating a warning event (e.g., displaying an alert that notifies a user that the respective warning threshold has been exceeded) or any other corrective action described herein. If any average spectral drift value exceeds their respective fault threshold, one or more corrective actions may be performed, such as generating a fault service, initiating an automated calibration process for the reflectometer or for some or all components of the processing system, adjusting processing parameters to compensate for measurement drift, triggering a system self-diagnostic routine to identify potential sources of error, performing a controlled system reset to restore stable operating conditions, or any other corrective action described herein.

At block 1214, the processing logic may determine or otherwise verify whether S21Ratio is within an acceptable band. To do so, the processing logic may determine whether data points of S21Ratio are within respective acceptable limits. A data point of S21Ratio may be within acceptable limits if the data point is below an upper threshold and above a lower threshold. According to embodiments, the upper and lower thresholds may be tailored to the wavelength to which the data point corresponds. As such, upper and lower thresholds of respective data points of S21Ratio may vary. These upper and lower thresholds may be predetermined based on historical S21Ratios and/or the known compositions of the silicon and silicon dioxide reference targets. For example, in one embodiment, the known silicon dioxide thickness(es) of the reference target may be used to compute a theoretical reflectivity spectrum using a transfer matrix method (TMM) (e.g. derived from Maxwell's equation). In at least some cases, the known compositions of the silicon and silicon dioxide reference targets, along with historical variations of data points corresponding to each wavelength tested by the reflectometer, may be used to determine the upper and lower thresholds of respective data points of S21Ratio.

According to embodiments, a corrective action may be performed if a threshold number of data points are not within acceptable limits. In some embodiments, a corrective action may be performed if at least approximately 5% of all measured data points are not within acceptable levels. In another embodiment, a corrective action may be performed if at least approximately 10% of all measured data points are not within acceptable levels. However, any suitable percentage of all measured data points may be used as a warning threshold or a limit threshold. The corrective action can include, but is not limited to, generating a warning event, generating a fault service, initiating an automated calibration process for the reflectometer or for some or all components of the processing system, adjusting processing parameters to compensate for measurement drift, triggering a system self-diagnostic routine to identify potential sources of error, performing a controlled system reset to restore stable operating conditions, or any other corrective action described herein.

At block 1216, the processing logic may use at least S2 to calculate and verify a film thickness measurement. In some embodiments, S21Ratio may be used to calculate and verify the film thickness measurement. Because silicon dioxide is a transparent dielectric over a broad range of wavelengths, incident light undergoes partial reflection at both the top surface of the film and the interface between silicon dioxide and the underlying substrate (e.g., silicon). These reflected waves interfere, producing a characteristic interference pattern in the spectral data. By measuring the intensity of reflected or transmitted light as a function of wavelength, the processing logic can extract the film thickness using, for example, thin-film interference models. One approach can involve fitting the measured spectrum to a theoretical reflectance or transmittance model, which considers factors such as the refractive index of silicon dioxide, the wavelength-dependent phase shift, and the absorption characteristics of the material. Mathematically, the thickness t of the silicon dioxide film can be estimated using the equation:

$$t = \frac{m λ}{2 {n}_{{SiO}_{2}}} ,$$

where m is the interference order, λ is the wavelength of light at a reflectance peak or trough, and 2n_{SiO2} is the refractive index of silicon dioxide (SiO₂) at that wavelength.

Once the film thickness is calculated, the processing logic may compare the calculated film thickness to a known film thickness of the silicon-silicon dioxide reference target. If the difference between the calculated film thickness and the known film thickness exceeds a threshold (e.g., a warning threshold, a fault threshold), a corrective action may be performed. The corrective action can include, but is not limited to, generating a warning event, generating a fault service, initiating an automated calibration process for the reflectometer or for some or all components of the processing system, adjusting processing parameters to compensate for measurement drift, triggering a system self-diagnostic routine to identify potential sources of error, performing a controlled system reset to restore stable operating conditions, or any other corrective action described herein.

At block 1218, the processing logic may verify a silicon spectrum quality using the multiple samples of S1. Here, the processing logic may generate an average of all the samples of S1 (referred to herein at S1Avg). The processing logic may generate any suitable number of samples of S1. In one embodiment, the processing logic may generate at least 50 samples of S1. Using the samples of S1 to calculate S1Avg, the processing logic may perform the following:

$$for each indexed data point i , S 1 Avg ( i ) = \frac{1}{N} {\sum }_{n = 1}^{N} S {1}_{n} ( i ) .$$

After determining S1Avg, the processing logic may normalize the data points of S1 using S1Avg (e.g., [0,1]) (herein referred to as S1AvgNormalized). To determine S1AvgNormalized, the processing logic may perform the following:

$$for each indexed data point i , S 1 AvgNormalized ( i ) = \frac{S 1 ( i )}{S 1 Avg ( i )} .$$

Then, the processing logic may determine one or more averaged values using S1AvgNormalized. For example, the processing logic may determine a first average value using data points of S1AvgNormalized that correspond to wavelengths within a first subrange (e.g., 300-400 nm) (S1AvgNormalizedWR1), a second average value using data points of S1AvgNormalized that correspond to wavelengths within a second subrange (e.g., 400-600 nm) (S1AvgNormalizedWR2), and a third average value using data points of S1AvgNormalized that correspond to wavelengths within a third subrange (e.g., 600-800 nm) (S1AvgNormalizedWR3). Here, each of S1AvgNormalizedWR1, S1AvgNormalizedWR2, or S1AvgNormalizedWR3 may be compared to one or more of a second warning threshold or a second fault threshold. In another embodiment, any of the S1AvgNormalizedWR1, S1AvgNormalizedWR2, or S1AvgNormalizedWR3 may be compared to a different warning or fault threshold. If one or more of S1AvgNormalizedWR1, S1AvgNormalizedWR2, or S1AvgNormalizedWR3 exceeds their respective warning threshold, one or more corrective actions may be performed, such as generating a warning event (e.g., displaying an alert that notifies a user that the respective warning threshold has been exceeded) or any other corrective action described herein. If one or more of S1AvgNormalizedWR1, S1AvgNormalizedWR2, or S1AvgNormalizedWR3 exceeds their respective fault threshold, one or more corrective actions may be performed, such as generating a fault service, initiating an automated calibration process for the reflectometer or for some or all components of the processing system, adjusting processing parameters to compensate for measurement drift, triggering a system self-diagnostic routine to identify potential sources of error, performing a controlled system reset to restore stable operating conditions, or any other corrective action described herein.

At block 1220, the processing logic may determine a drift ratio calculation using S1AvgNormalized, similar to the drift ratio calculation performed at block 1212. Drift in the calculated S1AvgNormalized over time may be caused by a number of factors, including but not limited to lamp intensity drift, reflectometer sensitivity drift, the aging of components of the reflectometer, temperature variations, humidity effects, or the like. To determine whether S1AvgNormalized has experienced spectral ratio drift, S1AvgNormalized may be compared to a historical S1AvgNormalized (herein referred to as PrevS1AvgNormalized). PrevS1AvgNormalized may be a most-recently determined historical S1AvgNormalized (e.g., a most recent historical execution of the method 1200). In another embodiment, PrevS1AvgNormalized may be a historical S1AvgNormalized that was determined during or directly after a most recent calibration of the reflectometer or processing system. To determine the drift in S1AvgNormalized (herein referred to as S1AvgNormalizedDrift), the processing logic may perform the following:

$$for each indexed data point i , S 1 AvgNormalizedDrift ( i ) = \frac{S 1 AvgNormalized ( i )}{PrevS 1 AvgNormalized ( i )} .$$

According to embodiments, the processing logic may determine at least one average value corresponding to S1AvgNormalizedDrift. This at least one average value may be compared to one or more of a third warning threshold or a third fault threshold. In at least one embodiment, the processing logic may determine multiple average value using data points of S1AvgNormalizedDrift that each correspond to a different wavelength subrange. For example, the processing logic may determine at least a first average value S1AvgNormalizedDriftWR1 that corresponds to a first wavelength subrange (e.g., 300-400 nm), a second average value S1AvgNormalizedDriftWR2 that corresponds to a second wavelength subrange (e.g., 400-600 nm), and a third average value S1AvgNormalizedDriftWR3 that corresponds to a third wavelength subrange (e.g., 600-800 nm). Here, each of the S1AvgNormalizedDriftWR1, S1AvgNormalizedDriftWR2, S1AvgNormalizedDriftWR3 may be compared to one or more of the third warning threshold or the third fault threshold. In another embodiment, any of the S1AvgNormalizedDriftWR1, S1AvgNormalizedDriftWR2, S1AvgNormalizedDriftWR3 may be compared to a different warning or fault threshold. If any of the S1AvgNormalizedDriftWR1, S1AvgNormalizedDriftWR2, S1AvgNormalizedDriftWR3 exceeds their respective warning threshold, one or more corrective actions may be performed, such as generating a warning event (e.g., displaying an alert that notifies a user that the respective warning threshold has been exceeded) or any other corrective action described herein. If any of the S1AvgNormalizedDriftWR1, S1AvgNormalizedDriftWR2, S1AvgNormalizedDriftWR3 exceeds their respective fault threshold, one or more corrective actions may be performed, such as generating a fault service, initiating an automated calibration process for the reflectometer or for some or all components of the processing system, adjusting processing parameters to compensate for measurement drift, triggering a system self-diagnostic routine to identify potential sources of error, performing a controlled system reset to restore stable operating conditions, or any other corrective action described herein.

At block 1222, the processing logic may verify that noise within the S1 samples is within acceptable limits. To do so, the processing logic may calculate a coefficients of variation (CVs) (also referred to as CV values) for each index i of the S1 samples (i.e., for each wavelength). As such, the processing logic may calculate a set of CVs that corresponds to the S1 samples. Each CV may represent a normalized measure of dispersion for its respective index i of the S1 samples. A higher CV represents more relative variability, while a lower CV suggests lower relative variability. To calculate the set of CVs for each index i of the S1 samples, the processing logic may perform the following:

$$for each indexed data point i , CV ( i ) = \frac{σ ( i )}{μ ( i )} ,$$

where σ is the standard deviation of a dataset including all data points of the S1 samples corresponding to the index i, and is the mean of the same dataset. The processing logic may then determine one or more maximum CVs of the set of CVs, and compare the one or more maximum CVs to one or more of a warning threshold or a fault threshold. For example, the processing logic may determine at least a first maximum CV of a first subset of the set of CVs that corresponds to a first subrange of wavelengths (e.g., 320-350 nm) and a second maximum CV of a second subset of the set of CVs that corresponds to a second subrange of wavelengths (e.g., 350-800 nm). Here, each of the first and second maximum CVs may be compared to a same warning threshold or a same fault threshold. In another embodiment, any of the first and second maximum CVs may be compared to a different warning or fault threshold. If any of the first and second maximum CVs exceeds their respective warning threshold, one or more corrective actions may be performed, such as generating a warning event (e.g., displaying an alert that notifies a user that the respective warning threshold has been exceeded) or any other corrective action described herein. If any of the first and second maximum CVs exceeds their respective fault threshold, one or more corrective actions may be performed, such as generating a fault service, initiating an automated calibration process for the reflectometer or for some or all components of the processing system, adjusting processing parameters to compensate for measurement drift, triggering a system self-diagnostic routine to identify potential sources of error, performing a controlled system reset to restore stable operating conditions, or any other corrective action described herein.

Additionally, at block 1222, the processing logic may calculate an average CV for each of a subset of the set of CVs. For example, the processing logic may determine a first average CV value using CVs of the set of CVs that correspond to wavelengths within a first subrange (e.g., 300-400 nm) (S1AvgNormalizedWR1), a second average CV value using CVs of the set of CVs that correspond to wavelengths within a second subrange (e.g., 400-600 nm) (S1AvgNormalizedWR2), and a third average CV value using CVs of the set of CVs that correspond to wavelengths within a third subrange (e.g., 600-800 nm). Here, each of the first, second, and third average CVs may be compared to one or more of a fourth warning threshold or a fourth fault threshold. In another embodiment, any of the first, second, or third average CVs may be compared to a different warning or fault threshold. If one or more of the first, second, or third average CVs exceeds their respective warning threshold, one or more corrective actions may be performed, such as generating a warning event (e.g., displaying an alert that notifies a user that the respective warning threshold has been exceeded) or any other corrective action described herein. If one or more of the first, second, or third average CVs exceeds their respective fault threshold, one or more corrective actions may be performed, such as generating a fault service, initiating an automated calibration process for the reflectometer or for some or all components of the processing system, adjusting processing parameters to compensate for measurement drift, triggering a system self-diagnostic routine to identify potential sources of error, performing a controlled system reset to restore stable operating conditions, or any other corrective action described herein.

At block 1224, the processing logic may calculate or otherwise determine a ratio between S1 and S3. This ratio may be referred to as S31Ratio (sample 31Ratio). 31Ratio may represent a difference between spectral data of the back reflection target over spectral data of silicon. To determine S31Ratio, the processing logic may perform the following:

$$for each indexed data point i , S 31 Ratio ( i ) = \frac{S 3 ( i )}{S 1 ( i )} .$$

According to embodiments, the processing logic may determine at least one average value corresponding to S31Ratio. This at least one average value may be compared to one or more of a fifth warning threshold or a fifth fault threshold. In at least one embodiment, the processing logic may determine multiple average values using data points of S31Ratio that each correspond to a different wavelength subrange. For example, the processing logic may determine at least a first average value S31RatioAvgWR1 that corresponds to a first wavelength subrange (e.g., 300-400 nm), a second average value S31RatioAvgWR2 that corresponds to a second wavelength subrange (e.g., 400-600 nm), and a third average value S31RatioAvgWR3 that corresponds to a third wavelength subrange (e.g., 600-800 nm). Here, each of S31RatioAvgWR1, S31RatioAvgWR2, S31RatioAvgWR3 may be compared to one or more of the fifth warning threshold or the fifth fault threshold. In another embodiment, any of S31RatioAvgWR1, S31RatioAvgWR2, S31RatioAvgWR3 may be compared to a different warning or fault threshold. If any of S31RatioAvgWR1, S31RatioAvgWR2, S31RatioAvgWR3 exceeds their respective warning threshold, one or more corrective actions may be performed, such as generating a warning event (e.g., displaying an alert that notifies a user that the respective warning threshold has been exceeded) or any other corrective action described herein. If any of S31RatioAvgWR1, S31RatioAvgWR2, S31RatioAvgWR3 exceeds their respective fault threshold, one or more corrective actions may be performed, such as generating a fault service, initiating an automated calibration process for the reflectometer or for some or all components of the processing system, adjusting processing parameters to compensate for measurement drift, triggering a system self-diagnostic routine to identify potential sources of error, performing a controlled system reset to restore stable operating conditions, or any other corrective action described herein.

FIG. 13 illustrates a model training workflow 1305 and a model application workflow 1317 for process drift determination, film thickness determination and/or substrate offset determination according to one embodiment. Model training workflow 1305 and model application workflow 1317 may be performed by processing logic executed by a processor of a computing device. One or more of these model training workflow 1305, 1317 may be implemented, for example, by one or more machine learning modules implemented on a processing device and/or other software and/or firmware executing on a processing device.

The model training workflow 1305 is to train one or more machine learning models (e.g., deep learning models) to perform one or more of determining, predicting, modifying, etc. tasks associated with process drift determination (e.g., determining parameter corrections to account for process drift occurrence), film thickness determination and/or substrate offset determination (also referred to as substrate center determination), CD determination, CD-bias determination, and so on. Model application workflow 1317 is to apply the one or more trained machine learning models to perform one or more of the determination tasks. One or more of the machine learning models may receive target reflectometry data 1310 (e.g., of the reference target that is integrated on substrate holder 206 of FIG. 2A to FIG. 2B), substrate reflectometry data 1312 (or other measurement data) and/or image data 1314 (or other measurement data).

Various machine learning outputs are described herein. Particular numbers and arrangements of machine learning models are described and shown. However, it should be understood that the number and type of machine learning models that are used and the arrangement of such machine learning models can be modified to achieve the same or similar end results. Accordingly, the arrangements of machine learning models that are described and shown are merely examples and should not be construed as limiting.

In embodiments, one or more machine learning models are trained to perform one or more of the below tasks. Each task may be performed by a separate machine learning model. Alternatively, a single machine learning model may perform each of the tasks or a subset of the tasks. Additionally, or alternatively, different machine learning models may be trained to perform different combinations of the tasks. In an example, one or a few machine learning models may be trained, where the trained machine learning (ML) model is a single shared neural network that has multiple shared layers and multiple higher level distinct output layers, where each of the output layers outputs a different prediction, classification, identification, etc. The tasks that the one or more trained machine learning models may be trained to perform are as follows:

a. Process drift determination—As a substrate is being processed in a processing chamber, a number of variables may change or drift as a function of time. For example, there may be temperature fluctuations, deposition/etch rate fluctuations, etc. that may affect the uniformity of the film thickness (e.g., uniformity profile) across the surface substrate that is being processed. Additionally, chemical build-up which may happen over longer time scales may affect the uniformity profile across the surface of the substrate. The model would receive target reflectometry data and determine parameters that should be adjusted for calibration of the sensor for reflectometry measurements.

b. Film thickness determination—In some embodiments, it is desirable to have a film thickness across the surface of the substrate which is as uniform as possible. In order to efficiently measure the uniformity profile of the substrate, the sensor measures a number of target positions on the substrate. The number of positions and the location of positions needs to be optimally determined to gain an accurate representation of the uniformity profile. A machine learning model may receive measurements of one or more target positions and determine that the number and location of the one or more target positions is sufficient to give an accurate representation of the uniformity profile.

c. Measurement determination—A sensor measures a number of target positions on the substrate. The number of positions and the location of positions may be measured to determine optical constants, roughness, film thickness, material properties, particles, and so on. A machine learning model may receive measurements of one or more target positions and determine that the number and location of the one or more target positions is sufficient to give an accurate representation of a uniformity profile.

d. Substrate offset/center determination of substrate in IR system—One or more images may be generated by the camera while the substrate holder has one or more r, theta coordinate settings. These images and/or the r, theta coordinate settings of the substrate holder may be input into a trained ML model that outputs an indication of a center of the substrate. The ML model may output an offset of the substrate center relative to the substrate holder center (e.g., an x, y offset, or an r, theta offset) and/or a translation function for translating between a substrate-centered r, theta coordinate system and a substrate holder-centered r, theta coordinate system.

e. Substrate offset determination of substrate in process chamber-Sensor inferred data such as film thickness, CD, etc. at multiple target locations on a substrate can be used to generate a substrate map (e.g., wafer map). Data from the substrate map may be input into a trained ML model that outputs an inference of offset of placement of the substrate in a process chamber in which the substrate was previously processed.

One type of machine learning model that may be used to perform some or all of the above tasks is an artificial neural network, such as a deep neural network. Artificial neural networks generally include a feature representation component with a classifier or regression layers that map features to a desired output space. A convolutional neural network (CNN), for example, hosts multiple layers of convolutional filters. Pooling is performed, and non-linearities may be addressed, at lower layers, on top of which a multi-layer perceptron is commonly appended, mapping top layer features extracted by the convolutional layers to decisions (e.g. classification outputs). Deep learning is a class of machine learning algorithms that use a cascade of multiple layers of nonlinear processing units for feature extraction and transformation. Each successive layer uses the output from the previous layer as input. Deep neural networks may learn in a supervised (e.g., classification) and/or unsupervised (e.g., pattern analysis) manner. Deep neural networks include a hierarchy of layers, where the different layers learn different levels of representations that correspond to different levels of abstraction. In deep learning, each level learns to transform its input data into a slightly more abstract and composite representation. Notably, a deep learning process can learn which features to optimally place in which level on its own. The “deep” in “deep learning” refers to the number of layers through which the data is transformed. More precisely, deep learning systems have a substantial credit assignment path (CAP) depth. The CAP is the chain of transformations from input to output. CAPs describe potentially causal connections between input and output. For a feedforward neural network, the depth of the CAPs may be that of the network and may be the number of hidden layers plus one. For recurrent neural networks, in which a signal may propagate through a layer more than once, the CAP depth is potentially unlimited.

Training of a neural network may be achieved in a supervised learning manner, which involves feeding a training dataset consisting of labeled inputs through the network, observing its outputs, defining an error (by measuring the difference between the outputs and the label values), and using techniques such as deep gradient descent and backpropagation to tune the weights of the network across all its layers and nodes such that the error is minimized. In many applications, repeating this process across the many labeled inputs in the training dataset yields a network that can produce correct output when presented with inputs that are different than the ones present in the training dataset.

For model training workflow 1305, a training dataset containing hundreds, thousands, tens of thousands, hundreds of thousands or more target reflectometry data 1310 (e.g., determination of uniformity profiles at different points in time using different numbers and locations of target positions on substrates given a particular set of process conditions), substrate reflectometry data 1312 (e.g., one or more thickness profiles obtained by taking different numbers and/or locations of target positions of the substrate), and/or image data 1314 of a substrate on a substrate holder (optionally accompanied by position coordinates such as a linear position and a rotational position of the substrate holder) should be used to form a training dataset. Data may include, for example, a uniformity profile determined using a given number of measurements each associated with a particular target position. This data may be processed to generate one or more training datasets 1336 for the training of one or more machine learning models. The machine learning models may be trained, for example, to automatically calibrate the sensor between and/or during measurements of the substrate, and/or to automatically correct for process variations (such as changing conditions in the processing chamber, substrate placement that is offset from the center of the substrate holder, etc.) that may affect the measurement of the uniformity profile of the substrate, and/or to determine an offset of a substrate center relative to a substrate holder center.

In one embodiment, generating one or more training datasets 1336 includes gathering one or more target substrate reflectometry data and/or gathering one or more images of substrates on substrate holders with different offsets, orientations and/or substrate holder orientations/positions. The labels that are used may depend on what a particular machine learning model will be trained to do. For example, to train a machine learning model to perform process drift determination, a training dataset 1336 may include data labels indicative of reflectometry measurements of the reference target over time. To train an ML model to determine a center offset (e.g., determine a center of a substrate) labels may include offsets between a substrate center and a substrate holder center. As described in other embodiments the process recipes and/or process results may be represented as vectors and the process rates may be represented as one or more matrices.

To effectuate training, processing logic inputs the training dataset(s) 1336 into one or more untrained machine learning models. Prior to inputting a first input into a machine learning model, the machine learning model may be initialized. Processing logic trains the untrained machine learning model(s) based on the training dataset(s) to generate one or more trained machine learning models that perform various operations as set forth above. Training may be performed by inputting one or more of target reflectometry data 1310 and substrate reflectometry data 1312 into the machine learning model one at a time.

The machine learning model processes the input to generate an output. An artificial neural network includes an input layer that consists of values in a data point. The next layer is called a hidden layer, and nodes at the hidden layer each receive one or more of the input values. Each node contains parameters (e.g., weights) to apply to the input values. Each node therefore essentially inputs the input values into a multivariate function (e.g., a non-linear mathematical transformation) to produce an output value. A next layer may be another hidden layer or an output layer. In either case, the nodes at the next layer receive the input values from the output values generated by nodes at the previous layer, and each node applies weights to those values and then generates its own output value. This may be performed at each layer. A final layer is the output layer, where there is one node for each class, prediction and/or output that the machine learning model can produce.

Accordingly, the output may include one or more predictions or inferences. For example, an output prediction or inference may include one or more modifications to substrate reflectometry data (e.g., modifications based on calibration of the sensor). Processing logic may cause a substrate to be processed using the updated recipe (e.g., with the identified modifications) and receive an updated thickness profile. Processing logic may compare the updated thickness profile against a target thickness profile and determine whether a threshold criterion is met (e.g., thickness values measured across a surface of the substrate fall within a target threshold value window). Processing logic determines an error (i.e., a classification error) based on the differences between the updated thickness profile and the target thickness profile. Processing logic adjusts weights of one or more nodes in the machine learning model based on the error. An error term or delta may be determined for each node in the artificial neural network. Based on this error, the artificial neural network adjusts one or more of its parameters for one or more of its nodes (the weights for one or more inputs of a node). Parameters may be updated in a back propagation manner, such that nodes at a highest layer are updated first, followed by nodes at a next layer, and so on. An artificial neural network contains multiple layers of “neurons”, where each layer receives as input values from a set of neurons at a previous layer. The parameters for each neuron include weights associated with the values that are received from each of the neurons at a previous layer. Accordingly, adjusting the parameters may include adjusting the weights assigned to each of the inputs for one or more neurons at one or more layers in the artificial neural network.

Once the model parameters have been optimized, model validation may be performed to determine whether the model has improved and to determine a current accuracy of the deep learning model. After one or more rounds of training, processing logic may determine whether a stopping criterion has been met. A stopping criterion may be a target level of accuracy, a target number of processed images from the training dataset, a target amount of change to parameters over one or more previous data points, a combination thereof and/or other criteria. In one embodiment, the stopping criteria is met when at least a minimum number of data points have been processed and at least a threshold accuracy is achieved. The threshold accuracy may be, for example, 70%, 80% or 90% accuracy. In one embodiment, the stopping criterion is met if accuracy of the machine learning model has stopped improving. If the stopping criterion has not been met, further training is performed. If the stopping criterion has been met, training may be complete. Once the machine learning model is trained, a reserved portion of the training dataset may be used to test the model.

As an example, a machine learning model (e.g., process drift determiner 1367) is trained to determine changes in process parameters over time. A similar process may be performed to train machine learning models to perform other tasks such as those set forth above. A set of many (e.g., hundreds to millions) target reflectometry data may be collected and sensor calibration data 1369 may be determined.

Once one or more trained machine learning models 1338 are generated, they may be stored in model storage 1345, and may be added to process drift determiner 1367, measurement determiner 1364, substrate offset determiner 1380, and/or offset determiner 1365. Process drift determiner 1367, measurement determiner 1364, substrate offset determiner 1380, and/or offset determiner 1365 may then use the one or more trained machine learning models 1338 as well as additional processing logic.

For model application workflow 1317, according to one embodiment, input data 1362 may be input into process drift determiner 1367, which may include a trained neural network. Based on input data 1362, process drift determiner 1367 outputs information indicative of parameters that may need to be tuned to calibrate the sensor.

According to one embodiment, input data 1362 may include one or more images of a substrate on a substrate holder. The input data 1362 may further include a position and orientation of the substrate holder (e.g., as r, theta coordinates in a substrate holder-centered coordinate system). In one embodiment, the position and orientation is provided as a linear position (e.g., from a linear encoder associated with a linear actuator) and as a rotational position (e.g., from a rotational encoder associated with a rotational actuator). The input data 1362 may be input into substrate offset determiner 1365, which may output a center of the substrate. In one embodiment, the offset determiner 1365 outputs a substrate offset 1370 that indicates an offset between a center of the substrate holder and a center of the substrate. Based on the substrate offset 1370, a controller may determine coordinate transformations required for transforming between a substrate holder-centered coordinate system and a substrate-centered coordinate system. These transformations may be used to determine how to move a linear actuator during rotation of a substrate holder to ensure that a points at a target radius remain beneath a sensor during measurements of points at the radius on the substrate.

According to one embodiment, input data 1362 may be input into a measurement determiner 1364 (which may be a film thickness determiner, a CD deviation determiner, a particular count determiner, an optical constant determiner, etc.), which may include a trained neural network. Based on input data 1362, measurement determiner 1364 may generate one or more outputs related to critical dimensions, film thickness, optical constants, particle count, etc. referred to as measurement information 1366. In one embodiment, measurement information 1366 output by measurement determiner 1364 includes a map of measurement values across the substrate. In one embodiment, measurement information 1366 output by measurement determiner 1366 includes a map of measurements (e.g., deviations of CD from a specification over a surface of a substrate, CD-bias values, film thickness, etc.).

According to one embodiment, input data 1362 may be input into substrate offset determiner 1380, which may include a trained neural network. Based on input data 1362, substrate offset determiner 1380 may generate an output that indicates an offset that a previously processed substrate had while the substrate was in a process chamber that had processed the substrate. This information may be used to determine if a robot arm is placing substrates incorrectly in a process chamber, if lift pins are misaligned in a process chamber, and so on.

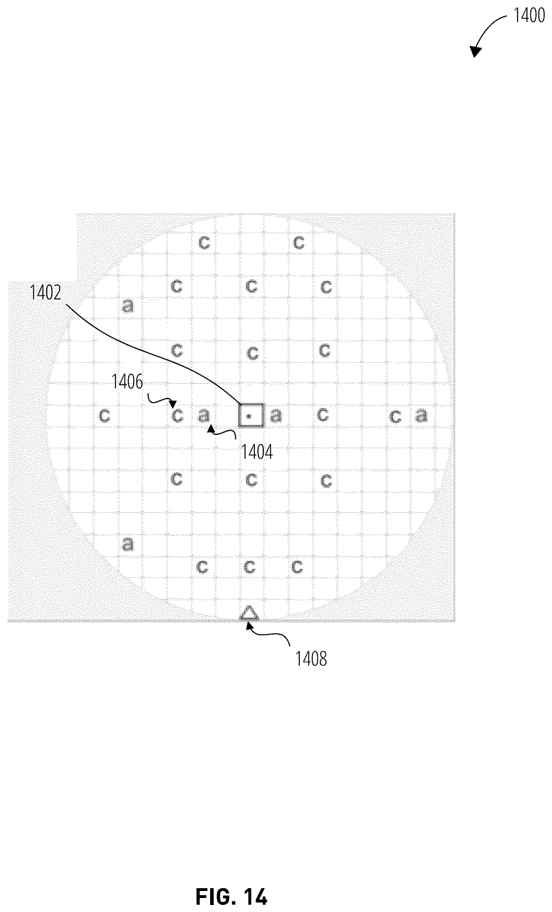

FIG. 14 illustrates a substrate pattern 1400 on a substrate with a notch 1408, according to one embodiment. According to embodiments, the substrate may have a circular shape. The substrate pattern 1400 may be imposed on the substrate based on the position of the notch.

In some embodiments, a primary (or first) alignment may be performed after a substrate is placed on the chuck of a substrate processing system, such as the processing system 800. This primary alignment may be designed to determine a directional offset between the center of the chuck and the center of the substrate, as well as a rotational orientation of the substrate. The primary alignment may involve capturing multiple images of the substrate edge and analyzing these images by comparing the actual position of the substrate edge in each image to an expected position of the substrate edge. Initially, the substrate may be placed on the chuck of the substrate processing system, which is equipped with a camera positioned above it to capture images of the substrate edge. The chuck is then rotated iteratively to capture multiple images of the substrate edge. In at least some embodiments, the resolution of these rotations are calibrated to ensure that the notch 1408 on the substrate edge is captured in at least one image. The number of images captured can vary based on the desired precision, ranging from at least 3 images for a basic alignment to 240 or more images for a higher-precision alignment.

The captured images may then be processed to detect the edge of the substrate, identifying the boundary of the substrate in each image and fitting the detected edge to a circle. The center of the fitted circle may represent the center of the substrate. The difference between the center of the fitted circle (substrate center) and the center of the chuck may then be calculated to determine the directional offset, indicating how much the substrate center is displaced from the chuck center in the x and y directions (e.g., 2-dimensional horizontal plane, x-y plane). The rotational offset may be determined by identifying the position of the notch 1408 on the substrate edge. By knowing the angular position of the notch relative to the chuck, the substrate processing system can calculate the rotational offset of the substrate with respect to the chuck.

Once the primary alignment is completed, the calculated directional and rotational offsets may be used to perform a secondary (or second) alignment. The secondary alignment may determine an orientation of the substrate pattern 1400 on the substrate. The secondary alignment can involve capturing images at multiple alignment points 1404, where the substrate has alignment marks. In at least one embodiment, at least one of these alignment points 1404 is located on or near a zero field of the substrate pattern 1400 (i.e., the center). For example, a first alignment point 1404 may be located in a corner (e.g., bottom-left corner) of the zero-field. The number of alignment points 1404 can vary based on the desired precision and/or a target runtime maximum, ranging from at least three alignment points 1404 for a basic alignment to at least five alignment points 1404. By comparing the actual position of the alignment marks in these images captured at the alignment points 1404 to their respective expected positions, an affine matrix may be calculated. The affine matrix may represent how the actual, observed spatial arrangement of pattern features disposed on the substrate is offset from an expected spatial arrangement of pattern features disposed on the substrate. The affine matrix may account for various types of offsets, including directional offsets, rotational offsets, and scaling (e.g., for substrate expansion or retraction due to temperature variation). The affine matrix may be calculated using the captured images at the alignment points 1404 and represents the transformation needed to align the substrate pattern 1400 with the expected spatial arrangement of pattern features disposed on the substrate. The directional offsets calculated during the primary alignment may be included in the affine matrix as translation components that account for the directional offsets between the substrate and the chuck. The affine matrix may also include the rotational offset calculated with respect to the primary alignment to account for the rotational offset of the substrate. Once the affine matrix is calculated, the substrate processing system may utilize the affine matrix to place one or more collection points 1406 underneath a reflectometer to collect spectrographic data (sometimes referred to as reflectometry data).

A step-by-step process for the primary and secondary alignments in at least some embodiments is as follows: A new substrate is placed on the chuck, and the chuck is positioned such that the edge of the substrate is underneath the camera. The chuck is iteratively rotated, and multiple images of the edge are captured. The captured images are analyzed to fit the edge to a circle, and the center of the fitted circle is compared to the center of the chuck to calculate the directional offset. The position of the notch 1408 on the edge of the substrate is identified, and the rotational offset is calculated. The calculated directional and rotational offsets are used to align the substrate with the chuck. Images are captured at the alignment points 1404 where the substrate has alignment marks. The affine matrix is calculated using the captured images at the alignment points, accounting for directional offsets, rotational offsets, and substrate expansion or retraction. The affine matrix is used to align the substrate pattern 1400 with the expected spatial arrangement of pattern features disposed on the substrate.

Using the affine matrix, an offset vector can be calculated for various different places (also referred to as positions) on the substrate pattern by applying the affine matrix to the expected coordinates of each position on the substrate. By transforming the coordinates of each point on the substrate using the affine matrix, the substrate processing system can determine the offset vector for each location. According to embodiments, this offset vector represents the difference between the actual position on the substrate and its respective expected position. The calculation of these offset vectors may be helpful for understanding the extent of misalignment between the substrate and the substrate processing system. Creating these offset vectors is helpful because it provides a detailed map of how much each point on the substrate deviates from its expected position. This information can help the substrate processing system determine and verify that the substrate is aligned with adequate tolerance to the chuck, which results in better yield in substrate processing (i.e., because substrates placed and/or oriented outside of tolerance thresholds will likely not be correctly processed). By comparing the offset vectors to predefined thresholds, the substrate processing system can assess the quality of the alignment. For example, the system can evaluate the maximum offset vector size to identify the largest deviation, and/or calculate the average offset vector to determine the overall alignment accuracy. If one or more of the offset vectors (or values derived using the offset vectors) exceed certain thresholds, corrective actions can be taken to realign the substrate. These corrective actions may include re-calibrating a substrate placement process, re-calibrating a chuck alignment process, or the like.

In addition to the primary and secondary alignments, alternative or additional alignment methods or techniques can be employed. One such method involves using a laser displacement sensor to detect the edge of the substrate. The laser displacement sensor can provide high-precision measurements of the substrate edge, allowing for accurate calculation of the offset between the centers of the chuck and substrate. Another alternative or additional method or technique includes using an optical encoder to measure the rotational position of the chuck. The optical encoder can provide precise feedback on the chuck's rotational position, enabling accurate alignment of the substrate pattern 1400. Furthermore, a hybrid alignment method can be utilized, combining one or more of the primary and secondary alignments with one or more machine learning algorithms. According to embodiments, the machine learning algorithm can analyze the captured images and predict the offset between the centers of the chuck and substrate based on historical data.

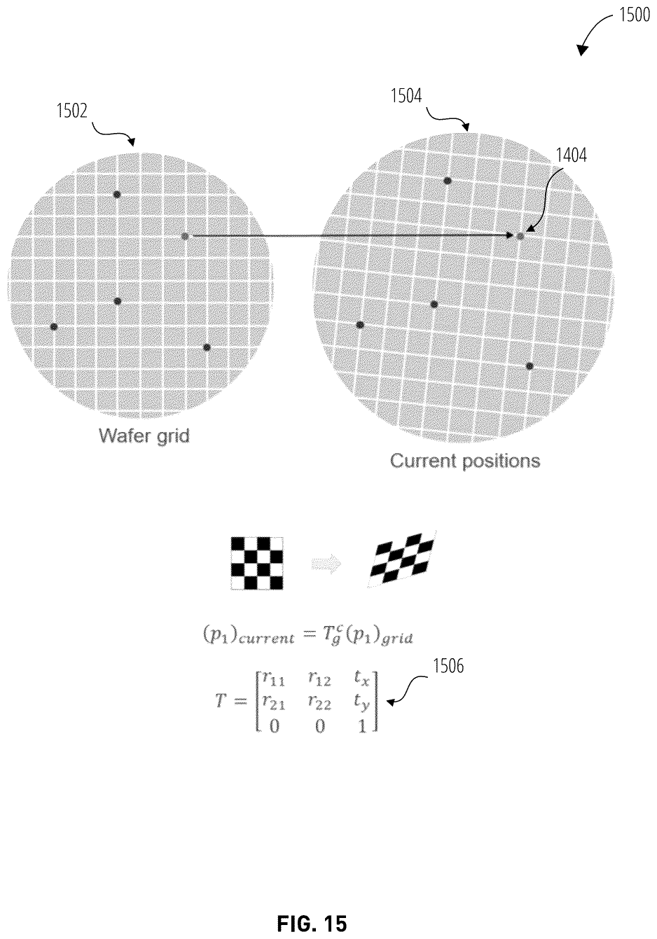

FIG. 15 illustrates an affine transform 1500, which is used to align an observed substrate pattern 1504 with an expected substrate pattern 1502, according to one embodiment. The affine transform 1500 may output an affine transform matrix 1506. According to embodiments, the affine transform matrix 1506 is a mathematical representation that accounts for various types of offsets and distortions, including directional offsets, rotational offsets, and scaling factors. These offsets and distortions may arise due to misalignments between the substrate and the chuck, as well as substrate expansion or contraction caused by temperature variations. The affine transform matrix 1506 may include translation components that account for directional offsets between the substrate and the chuck, rotation components that account for the rotational offset of the substrate, and/or scaling components that account for substrate expansion or contraction.

The expected substrate pattern 1502 represents the expected positions (or target positions) of alignment points 1404 on the substrate. As used herein, the “expected positions” of alignment points 1404, with respect to the camera, may refer to an initial reference point used to guide the secondary alignment described herein. In some cases, these “expected positions” may each correspond to a different default starting location with respect to a center of the chuck. Here, the “expected positions” of the alignment points 1404 may be the same each time that the respective verification process is performed. In another embodiment, these “expected positions” may each represent the last-known or last-calibrated position of the respective alignment points 1404. In some embodiments, these “expected positions” may be derived using a predictive model based on prior offset patterns or operational history.

In contrast, the observed substrate pattern 1504 (or actual substrate pattern) represents the actual positions of these alignment points 1404 as captured by the substrate processing system during the alignment process. The differences between the expected and observed substrate patterns may be used to calculate the affine transform matrix 1506.

The affine transform matrix 1506 may be calculated using the captured images at the alignment points 1404, where the substrate has alignment marks. By comparing the actual positions of the alignment marks in the observed substrate pattern 1504 to their respective expected positions in the expected substrate pattern 1502, the affine transform matrix 1506 may be determined. Once the affine transform matrix 1506 is calculated, it can be applied to the observed substrate pattern 1504 to align it with the expected substrate pattern 1502. This affine transform matrix 1506 may be used to align any target position of the substrate to an actual position of the substrate placed on the chuck. For example, the affine transform matrix 1506 may be applied to coordinates of an expected position of a particular point on the substrate (e.g., a collection point 1406) to generate coordinates of a corresponding actual position on the substrate.

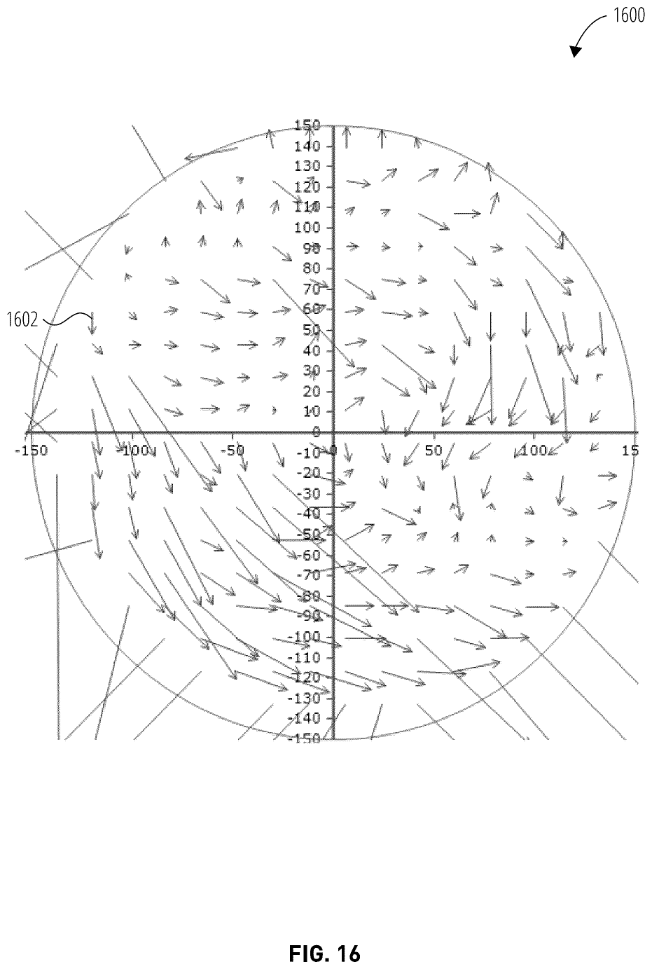

FIG. 16 illustrates a quiver plot 1600, which depicts error vectors 1602 for different positions on the substrate, according to one embodiment. The quiver plot 1600 may provide a visual and/or graphical representation of the magnitude and direction of errors (i.e., error vectors 1602) at various points on the substrate. Each error vector 1602 may indicate the deviation of a point on the substrate from its expected position, based on the alignment processes and calculated affine matrix described above with respect to at least FIG. 14 and FIG. 15. In other words, the error vectors 1602, when considered as a whole, represent how accurately the camera was positioned over the substrate and/or how accurately the wafer was positioned on the chuck.

The quiver plot 1600 can be generated at any resolution, meaning that the number of error vectors 1602 can be adjusted to provide more or less detail. Higher resolution quiver plots, with more error vectors, may offer a finer granularity of the error distribution across the substrate, allowing for a more detailed analysis of the alignment accuracy. Conversely, lower resolution quiver plots, with fewer error vectors, may provide a faster overview of the error distribution with less computational cost, at the cost of less accuracy.

These error vectors 1602 may be used to verify that operations associated with the positioning of the substrate on the chuck are correctly calibrated. In at least some cases, these error vectors 1602 are used to verify camera offset calibration for the IR system. By analyzing the quiver plot, the substrate processing system can determine whether the alignment process has been successful or if there are significant deviations that need to be addressed. If the quiver plot shows significant errors, targets may not be correctly or accurately placed under the reflectometer, which will lead to incorrect reflectometer results. As a result, the IR system as a whole can be impacted, including process monitoring and overall substrate yield. Error vectors exceeding predefined thresholds may indicate that the substrate processing system is to perform one or more corrective actions to improve alignment accuracy. Corrective actions to re-calibrate the substrate processing system and lower error vector magnitudes can include several methods, processes, or techniques. One approach can include re-calibrating a process that places the substrate on the chuck. This can include re-calibrating one or more center-finding (CF) processes of the substrate processing system. Another approach is to perform a re-calibration of the camera and sensors used in the alignment process. This can involve adjusting the camera and sensor positions to ensure they are accurately capturing the substrate edge and alignment marks. Another method is to refine the algorithm used to calculate the affine matrix, incorporating additional data points or using more advanced techniques to improve the accuracy of the alignment calculations. Additionally, the substrate processing system can employ machine learning algorithms to analyze historical alignment data and predict optimal calibration settings. By continuously learning from past alignment processes, the machine learning model can suggest adjustments to parameters of the substrate processing system that minimize error vectors in future alignments.

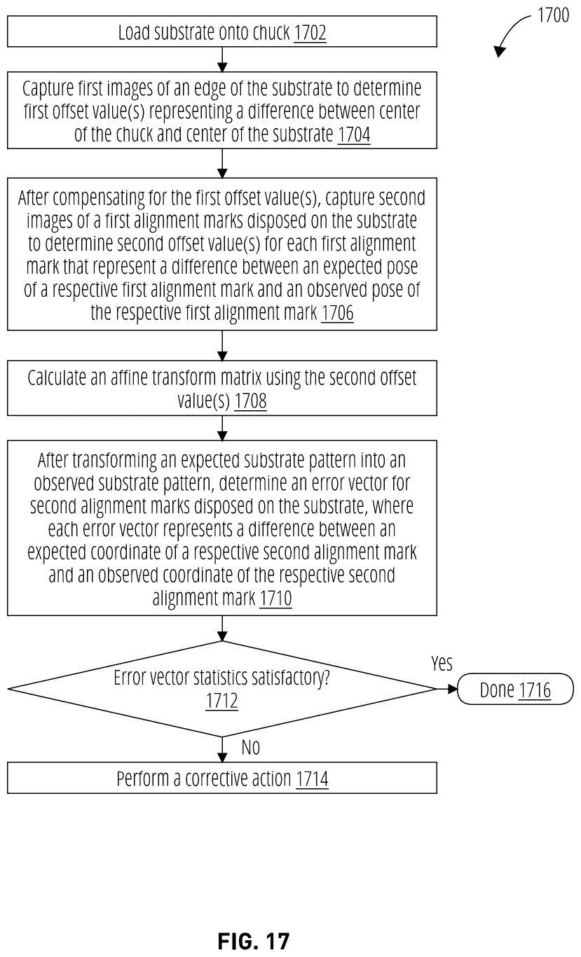

FIG. 17 illustrates a method 1700 of verifying an alignment of a substrate placed on a chuck or stage of a substrate processing system, according to one embodiment. According to embodiments, the method 1700 may be performed by processing logic that includes, hardware, software, firmware, or any combination thereof. In some embodiments, the processing logic includes memory storing instructions where, upon one or more processors executing the instructions, may cause the processing logic to perform the method 1700. In some embodiments, the method 1700 may be performed using one or more components of the processing system 100, imaging system 200, the IR system 300, and/or the processing system 800. The method 1700 may be performed according to descriptions above with respect to FIG. 14, FIG. 15, and/or FIG. 16. Other devices may perform the method 1200 as described herein.

At block 1702, the processing logic may load or otherwise place a substrate on a chuck. Then, at block 1704, a first (or primary) alignment verification operation is performed by capturing first image data corresponding to the edge of the substrate. This may involve rotating the chuck and capturing a plurality of images of the edge of the substrate, where each of the plurality of images corresponds to a different portion of the edge of the substrate, and at least one image captures a notch on the edge of the substrate. Using the first image data, one or more offset values representing the offset between the center of the chuck and the center of the substrate are determined. These one or more offset values may also include a rotational offset representing a difference between an expected location of the notch (or default position) and the actual position of the notch.

At block 1706, the processing logic may, by compensating based on the one or more offset values, perform a second (or secondary) alignment verification operation. This can involve capturing second image data corresponding to a first plurality of alignment marks on the substrate. The second alignment verification operation can include capturing a first image that captures a first alignment mark of the substrate corresponding to a zero field and capturing at least two other images that each capture different alignment marks on the substrate.

At block 1708, the processing logic may, using the first image and the at least two other images, calculate an affine transform matrix. The processing logic may calculate the affine transform matrix by comparing the actual observed positions of these alignment marks to expected (or default) positions of the respective alignment marks. This affine transform matrix may be capable of transforming the expected pose of the first alignment mark to the observed pose of the first alignment mark.

At block 1710, the processing logic may, using the affine transform matrix, determine error vectors for at least each of a plurality of alignment marks disposed on the substrate. The processing logic may determine these error vectors by comparing an expected spatial arrangement of the pattern features disposed on the substrate to the actually observed orientation of the pattern features disposed on the substrate. In at least some embodiments, error vectors for positions on the substrate other than the alignment marks used during the second alignment operation may be calculated using the affine transform matrix. Each error vector may represent a difference between the expected coordinate of a respective alignment mark and the observed coordinate (or estimated actual coordinate, if not actually observed) of the respective alignment mark. The plurality of alignment marks may comprise at least four alignment marks.

At decision block 1712, the processing logic may determine whether one or more statistics related to the error vectors determined at block 1710 are satisfactory. According to embodiments, the processing logic may determine one or more of a maximum error vector, a mean magnitude of error vector, a mean absolute error (MAE), a root mean square error (RMSE), a normalized histogram of magnitudes of the error vectors, a covariance matrix of the error vectors, an angular spread of error vectors, an outlier analysis of the error vectors, or the like. These statistical characteristics may be compared to one or more thresholds (e.g., warning thresholds, limit thresholds). If the error vector statistics are satisfactory, the processing logic may complete performing the method 1700 at done block 1716. However, if one or more of the error vector statistics are not satisfactory (e.g., satisfy a threshold), a corrective action may be performed at block 1714. Corrective action(s) to re-calibrate the substrate processing system and lower error vector magnitudes can include several methods, processes, or techniques. One approach can include re-calibrating a process that places the substrate on the chuck. This can include re-calibrating one or more center-finding (CF) processes of the substrate processing system. Another approach is to perform a re-calibration of the camera and sensors used in the alignment process. This can involve adjusting the camera and sensor positions to ensure they are accurately capturing the substrate edge and alignment marks. Another method is to refine the algorithm used to calculate the affine matrix, incorporating additional data points or using more advanced techniques to improve the accuracy of the alignment calculations. Additionally, the substrate processing system can employ machine learning algorithms to analyze historical alignment data and predict optimal calibration settings. By continuously learning from past alignment processes, the machine learning model can suggest adjustments to parameters of the substrate processing system that minimize error vectors in future alignments.

According to embodiments, the affine matrix may represent the determining of the orientation of the spatial arrangement of pattern features disposed on the substrate. As described herein, calculating the affine matrix can involve determining one or more offset values that represent the difference between the center of the substrate and the first alignment mark. Additionally, a pitch value representing the angular offset (also referred to herein as rotational offset) of the orientation of the spatial arrangement of pattern features with respect to the notch on the edge of the substrate may be determined and used to calculate the affine matrix, as described herein.

In at least some embodiments, if the processing logic determines that the error vector statistics are satisfactory at decision block 1712, the processing logic may use the one or more offset values and the orientation of the spatial arrangement of pattern features disposed on the substrate (e.g., the affine matrix) to perform a reflectometry operation. This reflectometry operation may be performed to verify the quality of one or more characteristics of the substrate placed loaded onto the chuck. This may involve capturing reflectometry data corresponding to a second plurality of alignment marks on the substrate. In at least one embodiment, the first plurality of alignment marks and the second plurality of alignment marks are mutually exclusive.

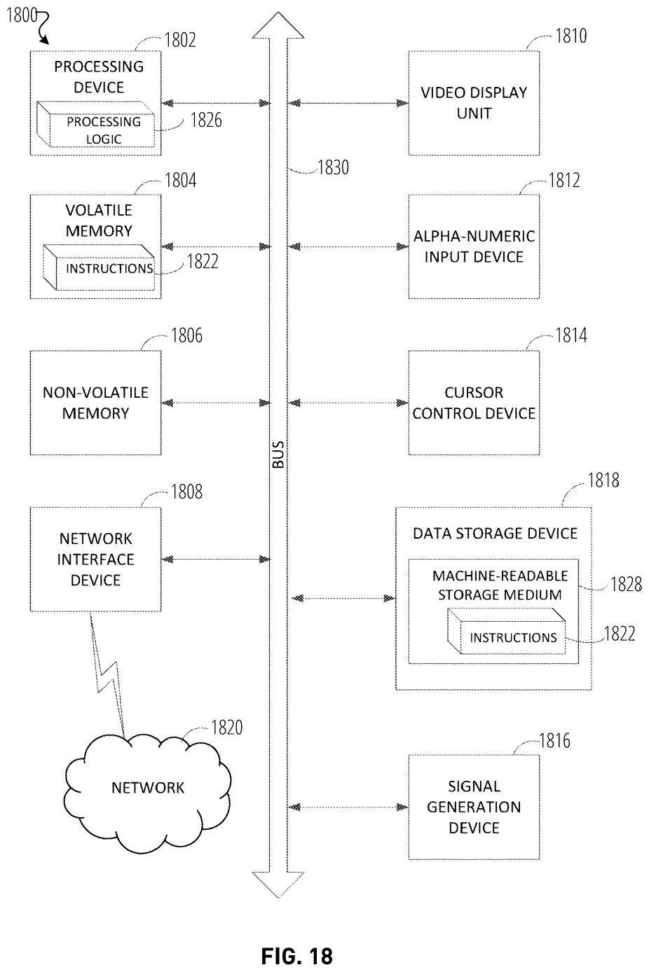

FIG. 18 depicts a block diagram of an example computing device 1800 capable of performing reflectometry verification or calibration, camera offset verification or calibration, reflectometry offset verification or calibration, and/or substrate alignment verification or calibration, operating in accordance with one or more aspects of the disclosure. In various illustrative examples, various components of the computing device 1800 may represent various components of a computing device, controller, and/or control panel (e.g., analogous elements described in association with FIG. 1 to FIG. 3). According to embodiments, the computing device 1800 may be configured to perform one or more of the processes, methods, or techniques described herein. For example, the computing device 1800 may be configured to perform one or more of the methods 600, 700, 900, 1100, 1200, 1300, or 1700.

Example computing device 1800 may be connected to other computer devices in a local area network (LAN), an intranet, an extranet, and/or the Internet. Computing device 1800 may operate in the capacity of a server in a client-server network environment. Computing device 1800 may be a personal computer (PC), a set-top box (STB), a server, a network router, switch or bridge, or any device capable of executing a set of instructions (sequential or otherwise) that specify actions to be taken by that device. Further, while only a single example computing device is illustrated, the term “computer” shall also be taken to include any collection of computers that individually or jointly execute a set (or multiple sets) of instructions to perform any one or more of the methods discussed herein.

Example computing device 1800 may include a processing device 1802 (also referred to as a processor or CPU), a main memory 1804 (e.g., read-only memory (ROM), flash memory, dynamic random access memory (DRAM) such as synchronous DRAM (SDRAM), etc.), a static memory 1806 (e.g., flash memory, static random access memory (SRAM), etc.), and a secondary memory (e.g., a data storage device 1818), which may communicate with each other via a bus 1830.

Processing device 1802 represents one or more general-purpose processing devices such as a microprocessor, central processing unit, or the like. More particularly, processing device 1802 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 1802 may also be one or more special-purpose processing devices such as an application specific integrated circuit (ASIC), a field programmable gate array (FPGA), a digital signal processor (DSP), network processor, or the like. In accordance with one or more aspects of the disclosure, processing device 1802 may be configured to execute instructions implementing methods 600, 700, 900, 1100, 1200, 1300, or 1700 illustrated in FIG. 6 to FIG. 17.

Example computing device 1800 may further comprise a network interface device 1808, which may be communicatively coupled to a network 1820. Example computing device 1800 may further comprise a video display 1810 (e.g., a liquid crystal display (LCD), a touch screen, or a cathode ray tube (CRT)), an alphanumeric input device 1812 (e.g., a keyboard), a cursor control device 1814 (e.g., a mouse), and an acoustic signal generation device 1816 (e.g., a speaker).

Data storage device 1818 may include a machine-readable storage medium (or, more specifically, a non-transitory machine-readable storage medium) 1828 on which is stored one or more sets of executable instructions 1822. In accordance with one or more aspects of the disclosure, executable instructions 1822 may comprise executable instructions associated with executing methods 600, 700, 900, 1100, 1200, 1300, or 1700 illustrated in FIG. 6 to FIG. 17.

Executable instructions 1822 may also reside, completely or at least partially, within main memory 1804 and/or within processing device 1802 during execution thereof by example computing device 1800, main memory 1804 and processing device 1802 also constituting computer-readable storage media. Executable instructions 1822 may further be transmitted or received over a network via network interface device 1808.

While the computer-readable storage medium 1828 is shown in FIG. 18 as a single medium, the term “computer-readable storage medium” should be taken to include a single medium or multiple media (e.g., a centralized or distributed database, and/or associated caches and servers) that store the one or more sets of operating instructions. The term “computer-readable storage medium” shall also be taken to include any medium that is capable of storing or encoding a set of instructions for execution by the machine that cause the machine to perform any one or more of the methods described herein. The term “computer-readable storage medium” shall accordingly be taken to include, but not be limited to, solid-state memories, and optical and magnetic media.

Some portions of the detailed descriptions above are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “identifying,” “determining,” “storing,” “adjusting,” “causing,” “receiving,” “comparing,” “measuring,” “correcting,” “applying,” “using,” “obtaining,” “replacing,” “performing,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Examples of the disclosure also relate to an apparatus for performing the methods described herein. This apparatus may be specially constructed for the target purposes, or it may be a general purpose computer system selectively programmed by a computer program stored in the computer system. Such a computer program may be stored in a computer readable storage medium, such as, but not limited to, any type of disk including optical disks, compact disc read only memory (CD-ROMs), and magnetic-optical disks, read-only memories (ROMs), random access memories (RAMs), erasable programmable read-only memory (EPROMs), electrically erasable programmable read-only memory (EEPROMs), magnetic disk storage media, optical storage media, flash memory devices, other type of machine-accessible storage media, or any type of media suitable for storing electronic instructions, each coupled to a computer system bus.

The methods and displays presented herein are not inherently related to any particular computer or other apparatus. Various general purpose systems may be used with programs in accordance with the teachings herein, or it may prove convenient to construct a more specialized apparatus to perform the method steps. The structure for a variety of these systems will appear as set forth in the description below. In addition, the scope of the disclosure is not limited to any particular programming language. It will be appreciated that a variety of programming languages may be used to implement the teachings of the disclosure.

The preceding description sets forth numerous specific details such as examples of specific systems, components, methods, and so forth, in order to provide a good understanding of several embodiments of the disclosure. It will be apparent to one skilled in the art, however, that at least some embodiments of the disclosure may be practiced without these specific details. In other instances, well-known components or methods are not described in detail or are presented in simple block diagram format in order to avoid unnecessarily obscuring the disclosure. Thus, the specific details set forth are merely exemplary. Particular implementations may vary from these exemplary details and still be contemplated to be within the scope of the disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A device comprising:
a chuck that is moveable in an x-y plane, the chuck comprising a calibration target attached to the chuck;
a camera; and
a controller to:
cause the chuck to move to a first chuck position at which the calibration target is in a field of view of the camera;
cause the camera to capture an image of the calibration target;
determine, using the image, a first actual position of the calibration target;
determine a first offset value corresponding to a difference between a first expected position of the calibration target and the first actual position of the calibration target; and
verify a calibration of the camera using one or more of the first expected position of the calibration target or the first actual position of the calibration target.

2. The device of claim 1, further comprising a reflectometer, wherein the controller is further to:
cause the chuck to move to a second chuck position at which the calibration target is in a field of view of the reflectometer, wherein the second chuck position is determined based on one or more of the first expected position of the calibration target or the first actual position of the calibration target;
cause the reflectometer to perform a scan to determine a second actual position of the calibration target; and
calculate a second offset value corresponding to a difference between a second expected position of the calibration target and the second actual position of the calibration target; and
responsive to determining that the second offset value exceeds a first threshold, perform one or more corrective actions.

3. The device of claim 2, wherein the controller is further to:
determine that the first offset value does not exceed a second threshold, wherein verifying a calibration of the reflectometer is performed based on the first offset value not exceeding the second threshold.

4. The device of claim 2, wherein the first offset value is associated with a first drift parameter corresponding to the camera, and wherein the second offset value is associated with a second drift parameter corresponding to the reflectometer.

5. The device of claim 2, wherein to perform the scan, the controller is to:
identify a grid of additional chuck positions based on the second chuck position;
iteratively alternate between moving the chuck to one of the additional chuck positions of the grid and generating a spectral frame using the reflectometer until a respective spectral frame has been generated for each additional chuck position of the grid; and
compare spectral frames to determine the second actual position of the calibration target.

6. The device of claim 5, wherein to compare the spectral frames, the controller is to:
perform a Gaussian fit to values of the spectral frames.

7. The device of claim 1, wherein the controller is further to:
determine a second offset value corresponding to a difference between a first expected position of the calibration target and the first actual position of the calibration target; and
determine that the first offset value does not exceed a first threshold and the second offset value does not exceed a second threshold, wherein verifying the calibration of a reflectometer of the device is conditional on the first offset value not exceeding the first threshold and the second offset value not exceeding the second threshold.

8. The device of claim 1, wherein to determine the first actual position of the calibration target, the controller is to:
determine that the image does not capture a threshold spatial coverage of the calibration target; and
iteratively alternate between moving the chuck to a different chuck position and capturing an additional image until the additional image captures more than the threshold spatial coverage of the calibration target.

9. The device of claim 1, wherein to determine the first actual position of the calibration target, the controller is to:
determine that the image does not capture the calibration target in at least a portion of each quadrant of the image; and
perform an edge detection to identify an edge of the calibration target within each quadrant of the image; and
determine the first actual position of the calibration target using identified edges of the calibration target.

10. A method of determining drift characteristics of a substrate processing device comprising a camera, a reflectometer, and a chuck that is moveable in an x-y plane, the chuck comprising a calibration target attached to the chuck, the method comprising:
moving the chuck to a first chuck position at which the calibration target is in a field of view of the camera;
capturing an image of the calibration target using the camera;
determining, using the image, a first actual position of a calibration target attached to the chuck;
determining a first offset value corresponding to a difference between a first expected position of the calibration target and the first actual position of the calibration target; and
verifying a calibration of the camera using one or more of the first expected position of the calibration target or the first actual position of the calibration target.

11. The method of claim 10, wherein the method further comprises:
moving the chuck to a second chuck position at which the calibration target is in a field of view of the reflectometer, wherein the second chuck position is determined based on one or more of the first expected position of the calibration target or the first actual position of the calibration target;
performing a scan using the reflectometer to determine a second actual position of the calibration target; and
calculating a second offset value corresponding to a difference between a second expected position of the calibration target and the second actual position of the calibration target; and
based on the second offset value exceeding a first threshold, performing one or more corrective actions.

12. The method of claim 11, further comprising:
determining that the first offset value does not exceed a second threshold, wherein verifying a calibration of the reflectometer is performed based on the first offset value not exceeding the second threshold.

13. The method of claim 11, wherein the first offset value is associated with a first drift parameter corresponding to the camera, and wherein the second offset value is associated with a second drift parameter corresponding to the reflectometer.

14. The method of claim 11, wherein performing the scan comprises:
identifying a grid of additional chuck positions based on the second chuck position;
iteratively alternating between moving the chuck to one of additional chuck positions of the grid and generating a spectral frame using the reflectometer until a respective spectral frame has been generated for each additional chuck position of the grid; and
comparing spectral frames to determine the second actual position of the calibration target.

15. The method of claim 14, comparing the spectral frames comprises:
performing a Gaussian fit to values of the spectral frames.

16. The method of claim 10, further comprising:
determining a second offset value corresponding to a difference between a first expected position of the calibration target and the first actual position of the calibration target; and
determining that the first offset value does not exceed a first threshold and the second offset value does not exceed a second threshold, wherein verifying the calibration of the reflectometer is conditional on the first offset value not exceeding the first threshold and the second offset value not exceeding the second threshold.

17. The method of claim 10, wherein determining the first actual position of the calibration target comprises:
determining that the image does not capture a threshold spatial coverage of the calibration target; and
iteratively alternating between moving the chuck to a different chuck position and capturing an additional image until the additional image captures more than the threshold spatial coverage of the calibration target.

18. The method of claim 10, wherein determining the first actual position of the calibration target comprises:
determining that the image does not capture the calibration target in at least a portion of each quadrant of the image; and
performing an edge detection to identify an edge of the calibration target within each quadrant of the image; and
determining the first actual position of the calibration target using the identified edges of the calibration target.

19. A device comprising:
a calibration target attached to a chuck that is moveable in an x-y plane;
a camera;
a reflectometer;
one or more processing devices; and
memory storing instructions that, when executed by the one or more processing devices, cause the device to:
determine, using the camera, a first actual position of the calibration target;
after moving the chuck to a first chuck position based on the first actual position of the calibration target, perform a scan using the reflectometer to determine a second actual position of the calibration target; and
calculate an offset value corresponding to a difference between an expected position of the calibration target and the second actual position of the calibration target; and
based on the offset value exceeding a threshold, perform one or more corrective actions.

20. The device of claim 19, wherein to perform the scan, the instructions cause the device to:
identify a grid of additional chuck positions based on the first chuck position;
iteratively alternate between moving the chuck to one of the additional chuck positions of the grid and generating a spectral frame using the reflectometer until a respective spectral frame has been generated for each of the additional chuck positions of the grid; and
comparing spectral frames to determine the second actual position of the calibration target.
